(19) United States
(12) Patent Application Publication
(10) Pub. No.: US 2005/0057906 A1
(43) Pub. Date: Mar. 17, 2005

(54) Connector sheet and wiring board, and production processes of the same

(76) Inventors: Seiichi Nakatani, Hirakata-shi (JP); Tousaku Nishiyama, Nara-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/937,422

(22) Filed: Sep. 10, 2004

(30) Foreign Application Priority Data
Sep. 12, 2003 (JP) 2003-321326
Jan. 23, 2004 (JP) 2004-015265

(51) Int. Cl. H05K 1/03

(52) U.S. Cl. 361/771; 174/258; 174/260; 29/830

(57) ABSTRACT

There is provided a connector sheet which includes an insulation sheet substrate having a front surface and a rear surface opposing to the front surface, and electrically conductive members each passing through the sheet substrate along a thickness direction of the sheet substrate, and the front surface and the rear surface contain a thermoset resin, and have tackiness under a first condition and develop adhesiveness under a second condition which is different from the first condition.

### CROSS-REFERENCE TO RELATED APPLICATIONS

The present application claims priorities under 35 U.S.C. § 119 based on:
(1) Japanese Patent Application No. 2003-321326 (fined on Sep. 12, 2003, entitled “CONNECTOR SHEET, MODULE COMPRISING SUCH CONNECTOR SHEET, METHOD OF ELECTRICALLY CONNECTING CIRCUIT BOARD AND PROCESS OF PRODUCING MODULE COMPRISING CIRCUIT BOARD”, and
(2) Japanese Patent Application No. 2004-015265 (fined on Jan. 23, 2004, entitled “MULTI-LAYERED WIRING BOARD, MODULE COMPRISING MULTI-LAYERED WIRING BOARD AND PROCESS OF PRODUCING MODULE”. The contents of those applications are incorporated herein by references in their entirety.

### BACKGROUND OF THE INVENTION

1. Field of the Invention

The present invention relates to a connector sheet as a connection element and also a production process of such connector sheet which electrically connects an electric member to other electric member. Generally, such electric element is located on a wiring board, and a portion of the electric member which portion is to be connected is exposed. The electric member itself may be present alone, and it is therefore not necessarily formed on the wiring board. It is noted that the electrical member means a wiring layer (or wiring pattern) which is formed on a wiring board, an electric or electronic part as a separate member or the like. In the present specification, such wiring layer may be a wiring as a portion of the wiring layer, or may be a land, a pad or a terminal which is a portion of the wiring or which is provided for the wiring. The wiring may form a portion of an electric circuit. Throughout the present specification, the term “wiring layer” is intended to mean any one of those elements above mentioned as to the wiring layer.

Further, the present invention relates to a wiring board, especially a multi-layered wiring board (or a module) which is produced by using such connector sheet, and also relates to a process of producing such multi-layered wiring board. In addition, the present invention relates to a method of connecting an electric member wherein the above mentioned connector sheet is used.

2. Description of the Related Art

With development in sophistication and miniaturization of an electronic device in recent years, a semiconductor device which constitutes the electronic device has more pins, and various electronic parts are miniaturized, so that the number of wirings and a wiring density of a printed circuit board which includes a number of such devices and parts drastically increase. Particularly, dramatic increase of the number of leads/terminals from a semiconductor device increases the number of wirings to be connected thereto, and therefore a wiring layer on either or both sides of a printed circuit board become insufficient. As a result, a demand of a wiring board which further contains a wiring layer in the inside thereof is increasing. Such wiring layer is referred to as a multi-layered wiring board.

A glass/epoxy resin multi-layered wiring board as shown in FIG. 16 is widely used as the above mentioned multi-layered wiring board (see for example Japanese Patent Kokai Publication No. 09-148738). The multi-layered wiring board 2500 of FIG. 16 comprises an insulation layer 2150 which is made of a glass woven fabric as a reinforcement member impregnated with an epoxy resin which has been cured, and wiring layers 2151 on the both sides of the insulation layer 2150. The wiring layer 2151 is made of a copper foil, and a further insulation layer 2150′ is formed on the wiring layer 2151. A through hole 2152 is formed in the multi-layered wiring board 2500, a copper layer 2153 is formed on an inner surface of the through hole 2152 in the manner of plating the through hole. Further, a wiring layer 2154 is formed from a copper foil on an outermost surface of the multi-layered wiring board 2150. The multi-layered wiring board as shown in FIG. 16 is also referred to as a plated through hole having multi-layered wiring board.

In order to provide a wiring board of which wiring density is further higher, using a buildup method, a buildup multi-layered printed wiring board has been developed which is referred to as a buildup wiring board (see for example Japanese Patent Kokai Publication No. 08-213757). The buildup wiring board is formed by laminating, on a core board such as a glass/epoxy multi-layered wiring board (see FIG. 16), an insulation layer having a wiring layer followed by connecting an upper wiring layer and a lower wiring layer through via hole conductors (or via holes). Since only a required upper wiring layer and a required lower wiring layer can be connected at any required position through the via hole conductor in the buildup wiring board without forming a through hole which passes through all wiring layers so that wiring accommodation is good, spaces of such via holes are reduced so that a diameter of the via hole can be smaller, and a width of the wiring and a wiring pitch can also be smaller, which makes the higher density wiring possible.

The via hole conductor which connects wiring layers in the buildup wiring board is usually formed by plating (see for example Japanese Patent Kokai Publication No. 08-213757). Also, there has been developed a buildup wiring board wherein via hole conductors are formed by using an electric conductive paste, not plating. As a buildup wiring board wherein the conductive paste is used, and no core wiring board is used, for example ALIVH™ (see for example Japanese Patent Kokai Publication No. 06-268345) and B²it™ (see for example Japanese Patent Kokai Publication No. 08-111574) are exemplified. It is noted that related technique is disclosed in Japanese Patent Kokai Publication No. 11-17300.

In order to electrically connecting as predetermined a wiring layer (particularly a predetermined position thereof) as the electric member which is formed on a wiring board to other wiring layer (particularly a predetermined position thereof) as the electric member which is formed on other wiring board, a stacking connector is usually used which connects the both wiring boards mechanically and electrically. Such stacking connector is disclosed in for example Japanese Patent Kokai Publication No. 08-228059.

There has been developed electrical connection using an anisotropic conductive film (ACF) between wiring boards, and such connection is disclosed in Japanese Patent Kokai Publication Nos. 05-174889 and 06-268345. Further, there is a technique wherein a solder material is used as a connection member between wiring boards so as to ensure mechanical and electrical bonding between them (see for example Japanese Patent Kokai Publication No. 06-120671).

The glass/epoxy multi-layered wiring board has an advantage in that it can be produced inexpensively. However, high density wiring is not readily formed in the board, so that it is very difficult to highly densely install compact semiconductor devices having many pins (such as ball grid array packages (BGA), chip size packages (CSP), bear chip packages or the like) on the glass/epoxy multi-layered wiring board. In order to improve electrical performances of the electronic devices which contain such semiconductor devices, short distance wirings are required and the number of wirings per unit area is required to greatly increase. A multi-layered wiring board which allows thus increased wiring number should have finely patterned wiring layers and micro via holes, and also have a great versatility in locating the via holes. The multi-layered wiring layer by the through hole plating method needs large spaces for the formation of the via holes having a larger diameter, so that the number of the via holes and the locations thereof as to the fine wiring formation, which means a less versatility in wiring.

Compared with the multi-layered wiring board by the through hole plating method, the buildup wiring board having a high density wiring is more readily produced and it is thus suitable for highly densely installing the compact semiconductor devices having many pins. However, the production of the buildup wiring board is much more costly when compared with the multi-layered wiring board by the through hole plating method. This is because the number of the steps of the production process for the buildup wiring board is increased when the number of wiring layers to be built up is increased, and surface flattening of the wiring board is required for the formation of the finely patterned wiring.

When the above mentioned connecting techniques are used, it is possible to electrically connect one wiring board to the other one, but the inventors have noticed the following issues when considering the applications to currently prevail electric equipments, especially the applications to the wiring boards which are desired to be compact and allow the fine pitch wiring.

When the stacking connector is used for the formation of the electric connection, a space for installing the stacking connector is required on the wiring board, which adversely affects the miniaturization of the electronic devices. Further, when the wiring board is of a flexible type (for example, a polyimide made board), using the stacking connector makes it difficult to obtain an electronic device which is thin as a whole even with such flexible board having a less thickness. In Japanese Patent Kokai Publication No. 09-148738, a stacking connector is used with a rigid wiring board (like a usual printed circuit board). When a rigid stacking connector is to be used with the flexible board, the step to install such connector is relatively troublesome to carry out, which leads to reduce a throughput of the production process of the electronic devices. In addition, there is a limitation of the adaptation to narrow wiring pitch in the connecting technique using the stacking connector.

In the technique using the ACF, the adaptation to the narrow wiring pitch is easier compared with the stacking connector. However, connection inspection during carrying out connecting on the way is impossible since sufficient connection is ensured only after the ACF is completely connected to an object by curing the ACF. Therefore, repairing on the way of producing a module cannot be carried out. Therefore, even when the connection is found to be defective by the inspection after completing the connection formation, the connection cannot be recycled so that the module cannot be reused and there is no way other than wasting the module. As a result, the improvement of the productivity of the module is difficult.

Connection with soldering has a limitation to the adaptation to the narrow wiring pitch, and needs a high temperature to melt a solder material, which is not suitable for a low temperature processing. In addition, when more than two wiring layers are to be connected, various solder materials having different melting temperatures should be used so that an already applied solder material does not melt as described in Japanese Patent Kokai Publication No. 08-111574. Using such various soldering materials makes the connecting process complicated. In addition, a lead containing solder material may cause an environmental concern while using a lead free solder material may be costly and also lead to a connecting temperature increase.

### SUMMARY OF THE INVENTION

Considering the above matters, the present inventions have been made, and one of the purposes thereof is to provide a connection element which allows the repair on the way of the connecting procedure and also which is adaptable to the narrow wiring pitch. Other purpose is to use such connection element so as to preferably at a low cost, produce a multi-layered wiring board or a module which contains wiring layers (or wiring patterns) with a high wiring density and fine wiring pitch. A further purpose is to provide processes for producing such connection element, such multi-layered wiring board and such module respectively.

The present inventors have noticed that no connection element is available which is adaptable to the narrow pitch wiring and also which allows the repair on the way, and extensively studied so as to provide such connection element. At last, the inventors have come to an idea that when an insulation sheet member has tackiness on its surface and electric conductivity along a thickness direction of the sheet member, and also such sheet member has a feature to cure under a predetermined specific condition to adhere to an object, such sheet member makes it possible to inspect an electric conductivity state before the sheet member is cured, whereby the inventors have completed the present invention.

In one aspect, the present invention provides a connector sheet as such connection element which comprises an insulation sheet substrate having a front surface and a rear surface opposing to the front surface, and electrically conductive members each passing through the sheet substrate along a thickness direction of the sheet substrate wherein the front surface and the rear surface contain a thermoset resin (or thermosetting resin), and have tackiness under a first condition and develop adhesiveness under a second condition which is different from the first condition.

In the present specification, the “first condition” means a condition under which a curing reaction of the thermost resin is not completed, and particularly preferably a condition under which such curing reaction does not occur. However, under the first condition, the curing reaction may occur, but it is never completed. Whether the curing reaction occurs or not depends on a temperature to which the thermoset resin (therefore the front surface and/or the rear surface) is subjected. Since a curing reaction starting temperature depends on the kind of the thermost resin, whether or not the temperature to which the thermoset resin is subjected is higher than the curing reaction starting temperature determines whether or not the curing reaction occurs. When the temperature of the first condition allows the thermoset resin to occur (or proceed) (i.e. when the temperature is not lower than the curing reaction starting temperature, whether or not the curing reaction is completed depends on a period for which the thermoset resin is subjected to such temperature. Generally, when the period is longer, the curing reaction approached to the completion of the curing reaction. Generally, the first condition is lower than the curing reaction starting temperature. When a temperature of the first condition is not lower than the curing reaction starting temperature, the first condition includes in addition to such temperature, a period after which the curing reaction has not been completed yet. The period depends on also the kind of the thermoset resin as well as the temperature which is not lower than the curing reaction starting temperature. More concretely, the front surface and the rear surface of the sheet substrate preferably have a specific peel strength as the tackiness which is in the range mentioned below. In other words, the first condition is a condition (a temperature, or a temperature and a period at that temperature) to provide such a specific peel strength.

In the present specification, the “second condition” means a condition under which the curing reaction of the thermost resin is completed. It is noted that “complete(d)” does not necessarily mean that the extent to which the curing reaction has proceeded is 100%, and “complete(d)” includes an embodiment wherein the curing reaction is substantially completed such that a required adhesive force (for example, a specific peel strength which is larger than what is mentioned below) is provided as the adhesiveness upon connecting electric members when using the connector sheet according to the present invention. The extent to which the curing reaction has proceeded depends on a temperature to which the thermoset resin is subjected and which is not lower than the curing starting temperature as well as a period for which the thermoset resin is subjected to such temperature. Concretely, it is preferable that the second condition including the temperature and the period results in the front surface and the rear surface of the sheet substrate which surfaces have a specific peel strength which will be mentioned below.

In each of the above conditions, it is noted that the temperature may be of a specific figure or a specific range of the temperature, and the period may be of a specific figure or a specific range of the period.

In one preferable embodiment of the connector sheet according to the present invention, a material which forms the front surface and the rear surface of the sheet substrate comprises a resin composition which contains the thermoset resin, and concretely such composition may be at least one selected from the group consisting of:
(a) a combination (for example a mixture) of a silicone resin and a thermoset resin;
(b) a combination (for example a mixture) of a thermoplastic resin and a thermoset resin; and
(c) a combination (for example a mixture) of a ultraviolet curable resin and a thermoset resin.

The combination (a) is a mixture system of the silicone resin/thermoset resin wherein tackiness of the silicone resin and adhesiveness of the thermoset resin are used. The combination (b) is a mixture system of the thermoplastic resin/thermoset resin wherein tackiness of the thermoplastic resin is used which is developed when the thermoplastic resin is swollen in a liquid thermoset resin, and adhesiveness of the thermoset resin is used. The combination (c) is a mixture system of the UV curable resin/thermoset resin wherein tackiness of the UV curable resin which is developed through a pre-gelation phenomenon is used, and adhesiveness of the thermoset resin is used. As to the pre-gelation, only a mixture mass is irradiated with UV so as to cure only the surface portion of the mass, whereby gelation of only the surface portion proceeds so that the surface portion has the tackiness. It is noted that portions of the sheet substrate except for the front surface and the rear surface may be made of a material which is the same as or different from that forming the front surface and the rear surface. Therefore, a whole of the sheet substrate may be made of any of the above mentioned materials, and any known suitable manner in which a sheet is produced using any of the above mentioned material may be used for the formation of the sheet substrate. As such manner, for example the following may be used: application of a resin composition optionally containing a solvent to a carrier film in a doctor blade method, an offset printing method or a coater method.

As easily seen, the curing reaction of the thermoset resin has not been completed at the stage of the connector sheet, and it is particularly preferable that the themoset resin is in an uncured state wherein no curing reaction has not yet occurred. However, it is also preferable that the curing reaction has already proceeded to some extent and then stopped, namely the thermoset resin is in the semi-cured state (i.e. in the so-called B-stage state).

As the thermoset resin, the following may be exemplified: an epoxy resin, a phenol resin, a phenoxy resin, an unsaturated polyester resin and so on.

As the silicone resin, the following may be exemplified: any silicone resin which having the tackiness.

As the thermoplastic resin, the following may be exemplified: a polyvinyl chloride, a polyethylene, a polypropylene, a polyvinyl acetate, a polycarbonate, a thermoplastic polyimide and so on.

As the UV curable resin, the following may be exemplified: an epoxy acrylate, an urethane acrylate and so on. In addition to or in place of the UV curable resin, other photo-polymerizable or photo-curable resin or compound may be used.

It is noted that any other material may be used as far as it has the tackiness and the adhesiveness in combination. For example, it is possible to achieve a material which has such combined tackiness and adhesiveness using only or substantially only a thermoplastic resin. The latter “substantially only” means that the thermoplastic resin is mainly used and other kind of material as an auxiliary material may be used. For example, in a system wherein a solvent is added into a thermoplastic resin which is softened or melted at a high temperature, softening or swelling of the thermoplastic resin by the solvent provides the tackiness, and heating the system leads to the evaporation of the solvent which solidifies the thermoplastic resin, which provides the adhesiveness. In this case, no thermoset resin is required in the surfaces of the sheet substrate of the connector sheet according to the present invention, and the first and second conditions are those which provide the specific peal strengths explained below. It is to be noted that excessively heating may melt the thermoplastic resin to cause peeling off and attentions are therefore to be paid to connection reliability at a high temperature.

The above mentioned resin composition which forms the front and rear surfaces of the sheet substrate may further comprises a tacky material, which is preferably uniformly distributed in the composition. Such tacky material is for example a thermoplastic resin or a thermoset resin in the form of powder which is absorbing a solvent and swelling so as to show the tackiness. Such tacky material may be distributed through the composition by sufficiently mixing with the resin composition before forming into the sheet form. Also, the resin composition which forms the front and rear surfaces of the sheet substrate may further comprise a filler in addition to or in place of the tackiness substance.

In one embodiment of the connector sheet according to the present invention, all portions of the sheet substrate are made of the same material such as the above mentioned resin composition, and thus such material forms the sheet substrate including the front and rear surfaces.

In other embodiment of the connector sheet according to the present invention, layer portions of the sheet substrate which define the front and rear surfaces of the sheet substrate respectively have the tackiness and the adhesiveness as mentioned above, and the other portion (i.e. a middle portion or core layer) of the sheet substrate may have no such properties. In this embodiment, materials each forming the front surface layer and the rear surface layer respectively may be the same or different. Those materials of the layers on the both sides of the core layer correspond to the materials which form the front surface and the rear surface of the sheet substrate of the connector sheet. In one concrete embodiment, the materials forming the front and rear surfaces are different from each other, so that the front surface has a first adhesive force as a tack strength and the rear surface has a second adhesive force as a tack strength which is different from the first tack strength. It is noted that the tack strength is determined as a peel strength which will be described below. As explained above, since the first condition is preferably comprises a temperature at which the curing reaction does not occur and a room temperature usually causes no curing reaction, the front surface layer and the rear surface layer may be generally referred to as tacky layers. It is noted that the core layer is preferably made of a polyimide film, and an example of other preferable material for the core layer includes a layer in a cured state such as a woven or unwoven fabric of which impregnated curable resin is in a completely cured state, and a film of resin (for example, a thermoplastic resin film which does not melt or soften even under the second condition such as a polyimide file, a polyphenylene sulfide film, an aramid film or the like).

In any of connector sheets according to the present invention, when considering environments in which the connector sheets are used in the production of wiring boards, the first condition comprises a certain temperature or a certain temperature range preferably in the range between 0° C. and 80° C. and more preferably in the range between 30° C. and 60° C. When the curing reaction of the thermoset resin proceeds under such temperature or temperature range, the first condition further comprises a period even for which the curing reaction is not completed. It is noted that such temperature means a temperature in an ambient temperature of the connector sheet when it is applied to the electric members to be connected.

The second condition comprises a temperature or temperature range preferably in the range which is not lower than a temperature at which the thermoset resin starts to cure (or harden), i.e. the curing reaction starting temperature, preferably higher than the curing reaction starting temperature by 10° C., and more preferably by 20° C. or more. The temperature or temperature range of the second condition is usually higher than that of the first condition. As explained above, the period after which the curing reaction has been completed is potentially included by the second condition.

In any of the connector sheets according to the present invention, one preferable embodiment thereof comprises a release film which is placed on at least one of the front surface and the rear surface of the sheet substrate. As a result thereof, the connector sheet may be readily handled. In other preferable embodiment, the connector sheet comprises in addition to or in place of the release film, a wiring layer (or a wiring pattern) which is placed on at least one of the front surface and the rear surface of the sheet substrate. When the connector sheet includes the both of the wiring layer and the release film on one or each side thereof, the release film forms the outermost layer.

In any of the connector sheets according to the present invention, the tackiness under the first condition may be reduced and preferably substantially disappear under a third condition of a temperature which is lower than the temperature of the second condition. That is, the peel strength as a measure of the tackiness which strength will be explained later becomes smaller and preferably greatly smaller relative to that under the first condition.

In other aspect, the present invention provides a wiring board which comprises a wiring board and the connector sheet having the electrically conductive members passing through the connector sheet according to the present invention. For the purpose of avoiding confusion, the latter wiring board is referred to as a “product wiring board” while the former wiring board is referred to as a “wiring board element”, and thus, the product wiring board is produced by using the wiring board element. It is noted that the curing reaction of the thermoset resin of the connector sheet in the product wiring board has been completed so that the adhesiveness of the connector sheet functions for the connection. The wiring board element comprises an electric member on at least one surface (or side) thereof, which is electrically connected to the conductive members of the connector sheet as predetermined. The electric member of the wiring board element is preferably a wing layer, of which thickness is preferably not smaller than 12 μm.

It is noted that the connector sheet is preferably placed on not a whole of but a portion of one side (or surface) of the wiring board element. In other embodiment, the connector sheet is placed on a portion of each side of the wiring board element. The connector sheet located on a portion of the surface of the wiring board element is preferably according to the present invention as described above, but the connector sheet may be not necessarily have the tackiness or the adhesiveness as far as it comprises for example a sheet material of a material which includes a resin, electrically conductive members connecting a front and rear surfaces of such sheet material, and a wiring layer which is connected to such conductive members, and it can be placed on a portion of the surface of the wiring board element. Such sheet material comprising the wiring layer and the conductive members passing through the sheet material is referred to as a “sheet element” so as to distinguish it from the connector sheet according to the present invention. Such sheet element may correspond to the connector sheet, but it does not have to have the tackiness or the adhesiveness. Thus, the sheet material may be made of a resin composition which is conventionally used for the wiring boards. In the description hereinafter, the term “connector sheet” is used to explain embodiments of the present invention, and it would be readily understood that the “sheet material” may be used in place of the “connector sheet” when the tackiness and the adhesiveness are not necessary.

In one embodiment, the wiring board element may be a double-sided layer wiring board which includes two wiring layers or a multi-layered wiring board which includes more than two wiring layers, namely, it may be a wiring board which includes at least two wiring layers. In this embodiment, an outermost wiring layer corresponds to an electric member which is electrically connected to the conductive members of the connector sheet.

In other embodiment, the connector sheet may include a wiring layer on one ends of the conductive members, that is, the sheet substrate of the connector sheet may have such wiring layer on one side of the sheet substrate. In this embodiment, the conductive members of the connector sheet are connected to the outermost wiring layer of the wiring board element so that the wiring layer of the connector sheet is electrically connected to the outermost wiring layer through the conductive members. Optionally, the connector sheet may have the wiring layer on each side of the sheet substrate. A thickness of the wiring layer of the connector sheet is preferably not larger than 10 μm, and the wiring layer preferably contains a wiring portion of which wiring pitch is not larger than 200 μm.

For example, in one embodiment of a product wiring board of the present invention, the connector sheet comprises a wiring layer on one side of the sheet substrate which forms the connector sheet; and when the wiring board element is a double-sided layer wiring board or multi-layered wiring board, the wiring layer of the connector sheet in conjunction with at least two wiring layers of the such wiring board are included by the product wiring board, so that the product wiring board becomes a multi-layered wiring board having at least three wiring layers (i.e. a product multi-layered wiring board).

That is, such multi-layered wiring board comprises:
a wiring board element which comprises at least two wiring layers; and
a connector sheet which is attached to at least one surface (preferably a portion of at least one surface) of the wiring board element and which includes a wiring layer as an electric member;
wherein
the connector sheet comprises:
a sheet substrate including a front surface on which the wiring layer is formed as the electric member and a rear surface which is opposed to the front surface, and
a plurality of conductive members which pass through the sheet substrate along its thickness direction,
the conductive members of the connector sheet electrically connect the wiring layer of the connector sheet to the wiring layer of the wiring board element as predetermined. The connector sheet functions to partially increase the number of the wiring layers of the product wiring board by increasing the number of the wiring layers of the product wiring board portion where the connector sheet is placed compared with the number of the wiring layers in the other portion of the product wiring board (i.e. the number of the wiring layers of the wiring board element). It is noted that the connector sheet may have the wiring layer on each of the both sides thereof.

In a more concrete embodiment, the product wiring board comprises a wiring board element which comprises an outermost wiring layer as at least one electric member wherein an electronic part as an electric member is electrically connected to such wiring board element through the connector sheet. In this embodiment, the electronic part such as a semiconductor device is located on the connector sheet and such part is connected to the outermost wiring layer through the connector sheet. In other embodiment, the connector sheet may comprise in addition to the wiring layer, a passive part (for example, a capacitor), which is connected to the wiring layer as predetermined, and finally to the wiring layer of the wiring board element.

In other embodiment of the product wiring board, a connector sheet is located between two wiring board elements and electrically connects them with each other. That is, in this embodiment, one wiring board element is connected to the other wiring board element through the connector sheet. Particularly, the connector sheet (which is referred to as a first connector sheet) electrically connects as predetermined wiring layers as the electric members which are located on surfaces of two wiring board elements respectively (which are referred to as a first wiring board element and a second wiring board element respectively). Such product wiring board may further comprise a separate wiring board element which is opposed to the first or second wiring board element, wherein a separate connector sheet (which is referred to as a second connector sheet) located between the first or second wiring board element and the third wiring board element electrically connect them as predetermined.

Thus, in the above embodiment, the product wiring board comprises the two wiring board elements and the connector sheet between them wherein the electric members of those wiring board elements are connected with each other through the connector sheet. The plural conductive members are exposed at a first surface (such as a front surface) of the first connector sheet and also at a second surface opposing to the first surface, and the first wiring board element is bonded to the first surface while the second wiring board is bonded to the second surface, so that the first wiring board element and the second wiring board element are connected with each other through the conductive members of the connector sheet. When two wiring board elements are connected as described, physical properties of the wiring board elements (such as a thickness, an occupying area (i.e. a side area of the wiring board element), a hardness and the like) are not necessarily the same or similar. For example, one element is a flexible board while the other is a relatively rigid board. Thus, materials which form the wiring board elements, particularly insulation materials thereof may be different, in which the connector sheet according to the present invention is useful. In other embodiment, one element is thin while the other element is relatively thick and/or one element is large while the other element is small as to their occupying areas.

In other embodiment of the above mentioned product wiring board, there may be an additional wiring board element(s) and/or an additional connector sheet(s), wherein such connector sheet is located between the adjacent two wiring board elements. Therefore, the product wiring board of the present invention may comprise at least two wiring board elements which are adjacent to each other and at least one connector sheet which is located between the adjacent two wiring board elements, wherein each connector sheet electrically connects the electric members with each other which the wiring board elements includes respectively.

It is noted that in any embodiment of the present invention, the connector sheet includes a plurality of the conductive members, at least one of which connects the electric members with each other as predetermined. When the number of the conductive members is excessively large compared with the number of the electric connections to be formed, there may be a conductive member(s) which does not contribute to the electric connection between the electric members.

In one embodiment of the product multi-layered wiring board, at least one of the wiring board elements functions as a core wiring board element (i.e. a wiring board element which forms a main component (i.e. a core) in the product wiring board). Such core wiring board element generally comprises an organic resin (for example an epoxy resin), a reinforcement material (for example a glass fiber fabric substrate) impregnated with such resin and a metal layer (for example a patterned copper foil). In one embodiment, the core wiring board element has a surface undulation of not smaller than 5 μm. It is noted that the undulation is measured according to JIS as explained later.

In one concrete embodiment, the above mentioned product multi-layered wiring board comprises:
a wiring board element which comprises at least two wiring layers (for example, a core wiring board element) and a connector sheet having a wiring layer which connector sheet is located on (for example tightly bonded to) a portion of a surface of the wiring board element,
a first electronic part (for example a surface mount device) placed on the wiring board element, and
a second electronic part (for example a surface mount device) placed on the connector sheet.

The connector sheet may be any of the above mentioned ones according to the present invention (i.e. having the tackiness as well as the adhesiveness as described above) wherein the sheet substrate contains the wiring layer thereon which is electrically connected to the conductive members. The wiring layer is electrically connected to the second electronic part, so that the outermost wiring layer of the wiring board element is connected to the second electronic part through the conductive members of the connector sheet. In one embodiment, the second electronic part is a semiconductor device of which terminal pitch (or pin pitch) is not larger than 125 μm.

In such product multi-layered wiring board, when the wiring board element is a core wiring board element, and/or the electronic part is a surface mount device, such product wiring board may referred to as a “module”. The module comprises a double-sided layer core wiring board or a multi-layered core wiring board, and an electric member (such as a wiring layer) of the core wiring board element is connected, through the connector sheet, to other electric member (such as an electronic part like a surface mount device) which is electrically separated from the core wiring board element. Said other electric member may be a wiring layer, a wiring, a pad, a bump, a terminal or the like which is located on other wiring board element. The core wiring board element may be a product wiring board according to the present invention as described above.

In the present specification, the “product wiring board” means a wiring board which is freshly obtained by connecting a wiring board element by means of the connector sheet. Among those product wiring boards, the “module” is a product wiring board which is obtained by connecting a wiring board element which functions as a core and other electric member through the connector sheet, and which by itself provides a specific function. It is noted that the “product wiring board” has of a broad concept which includes the “module”. Since these terms are usually used arbitrarily dependent on individual, they are not necessarily required to be strictly distinguished, which is applicable to the present specification.

In one preferable embodiment, a through hole is formed through the wiring board element such as a core wiring board element. Also, in other embodiment, there are, on a surface of the wiring board element, formed a copper layer and a plated layer thereon which are patterned. When the connector sheet has the wiring layer, such wiring layer may be formed by transfer of a wiring layer from a transfer member to the connector sheet.

In one embodiment of the product wiring board, the connector sheet may be placed on each side of a member which functions as a spacer substrate, and such spacer substrate thus having the connector sheets may be used for connecting two wiring board elements. This embodiment is useful when the two wiring board elements are connected while a certain spacing is kept between the two elements. It is noted that there is no specific limitation as to the spacer substrate as far as it has a certain thickness, and electrically connects the conductive members of the connector sheets placed on its both sides. The space substrate may have any form and usually has an electrically conductive member which passes through an insulation material forming the spacer substrate and which optionally has a pad at its each end. The number of the conductive member may be plural. Generally the spacer substrate has no other member, electric part, wiring or the like. Thus, in this embodiment, the product wiring board comprises the spacer substrate having, on both sides, the connector sheets according to the present invention and the wiring board elements located on the both sides of such spacer substrate wherein one wiring board element is electrically connected to the other wiring board element through the spacer substrate and the connector sheet is present between the spacer substrate and each of the wiring board elements.

A further product wiring board according to the present invention comprises an electronic part (such as a surface mount device), a connector sheet according to the present invention and at least one wiring board element wherein the connector sheet is placed between the electronic part and the wiring board element, whereby the electronic part and an electric member of the wiring board element are electrically connected with each other. In one embodiment, the electronic part is a semiconductor chip of which terminals (or pins) are arranged two-dimensionally.

For example, the connector sheet according to the present invention may be produced in a process which comprises the following:
(1) preparing a sheet substrate by using the above explained material for the sheet substrate;
(2) forming a plurality of through holes which extends along a thickness direction of the sheet substrate; and
(3) filling thus formed through holes with an electrically conductive material.
   In the above process, any known and suitable manner may be used for carrying out any of the above steps.

In other embodiment, a release film is placed on at least one side of the sheet substrate prepared in the above step (1), and thereafter the through holes are formed. When the connector sheet includes the wiring layer, a metal foil is attached to the sheet substrate after its preparation, followed by patterning the foil so as to form the wiring layer. The formation of the patterned wiring layer may be carried out at any suitable stage. After the wiring layer formation, the release film may be optionally placed. Alternatively, the formation of the wiring layer is carried out by means of transfer, wherein a transfer member may contain, in addition to the wiring layer, an electric part such as a passive part like a capacitor which is connected to the wiring layer, and the wiring layer and the part are transferred together. The formation of the connector sheet as described above is preferably carried out under the first condition.

The product wiring board according to the present invention may be produced by the following process of producing a product wiring board which comprises the steps of:
(a) preparing a wiring board element which comprises a wiring layer as an electric member on at least one side thereof, other electric member, and the above explained connector sheet according to the present invention;
(b) tentatively adhering the connector sheet according to the present invention onto one side of the wiring board element (preferably a portion of one side of the wiring board element), so that the wiring layer of the wiring board element is electrically connected to the conductive members of the connector sheet as predetermined;
(c) tentatively adhering said other electric member onto the connector sheet, so that said other electric member is electrically connected to the conductive members of the connector sheet as predetermined; and
(d) inspecting electric connection between the wiring layer as the electric member of the wiring board element and said other electric member.

In the above process, upon the production of the product wiring board, the inspection is carried out so as to determine whether or not there is formed the electric connection as predetermined between the wiring board element having the wiring layer as the electric member and said other electric member (such as an electric part, a wiring layer of other wiring board element) through the connector sheet, and then (e) if the electric connection is proved to have no problem, the next step (the step (e) is carried out, that is, converting the tentative adhesion to permanent adhesion is carried out. In such process, the tentative adhesion in the steps (b) and (c) is carried out under the first condition while converting to the permanent adhesion is carried out under the second condition.

In other words, the above mentioned production process may be said to be a method of connecting the wiring board element to said other wiring board element using the connector sheet, which method comprises the steps of (a) to (c), preferably the steps (a) to (d) and more preferably the steps (a) to (e), and also said to be a method of inspecting the electric connection between the wiring board element and said other wiring board element while using the connector sheet, which method comprises the steps of (a) to (d). It is noted that when the tentative adhesion is carried out, it is preferable that a small pressure is applied such that the electric members to be connected approach toward each other, whereby the adhesion is facilitated. Also, upon the inspection, it is preferable that a force is applied along a such direction that the connector sheet is compressed during the inspection. The present invention provides a method of inspecting an electric connection state between two electric members which method comprises the steps of: (A) with using any one of the connector sheets according to the present invention as described above under the first condition, tentatively adhering one electric member to the front surface of the connector sheet and also tentatively adhering the other electric member to the rear surface of the connector sheet; and (B) inspecting thereafter the electric connection between the electric members. When the step (B) is carried out, it is preferable that a compressing force is applied to the connector sheet so that the electric members try to approach toward each other.

The connector sheet may have the wiring layer on its either or both sides which wiring layer is connected to the conductive members as explained above. In this case, such wiring layer(s) together with the conductive members electrically connects the electric member (such as a wiring layer) of the wiring board element and said other electric member in the step (b) or/and the step (c).

Said other electric member may be for example an electronic part, wherein the electric part is mounted onto the wiring board element in the step (c).

The steps (b) and (c) are carried out under the first condition. Therefore, exposed surfaces of the sheet substrate of the connector sheet have the tackiness so that one surface of the connector sheet adheres to an outermost surface of one side of the wiring board element, and the other surface of the connector sheet adheres to said other electric member, whereby the tentative electric connection is ensured between the electric member of the wiring board element and said other electric member through the connector sheet.

As explained above, when the electric connection state has proved to be good by the inspection of the step (d), thus tentatively adhered wiring board element, said other electric member and the connector sheet are subjected to the second condition so to convert the tentative adhesion to the permanent adhesion.

The above mentioned production process preferably further comprises the step of (f) releasing said other electric member from its tentative adhesion condition to the connector sheet, so that said other electric member is separated from the wiring board element after the electric connection state has proved to be failure by the inspection of the step (d). Alternatively, the wiring board element is released from its adhesion to the connector sheet.

In the above mentioned production process, after the step (f), a fresh wiring board element and/or electric member which corresponds to the separated wiring board element and/or said electric member may be prepared and then the steps (b) and/or (c) may be carried out again using fresh one, followed by the step (d). Then, depending the results of the inspection of the step (d), the step (e) or (f) is carried out.

It is noted that the step (f) may be carried out under a third condition which comprises a temperature lower than the temperature of the first condition, whereby the tackiness is reduced, so that the separation becomes easier.

In one embodiment, the present invention provides a process of producing a module comprising a wiring board element onto which an electronic part is mounted, the process comprising the steps of:
(i) placing the connector sheet according to the present invention on a wiring layer as an electric member of the wiring board element under the first condition so that the connector sheet is tentatively adhered to the wiring board element (whereby the wiring layer of the wiring board element and the conductive members of the connector sheet are electrically connected),
(ii) placing other wiring board element having other wiring layer as other electric member or a surface mount device as other electric member on the connector sheet under the first condition so that said other wiring board element or the surface mount device is tentatively adhered to the connector sheet (whereby said other wiring layer or the surface mount device and the wiring layer of the wiring board element are electrically connected through the conductive members of the connector sheet), and
(iii) converting the tentative adhesion between said other wiring board element or the surface mount device and the connector sheet and also the tentative connection between the connector sheet and the wiring board element into the permanent adhesion under the second condition.

It is noted that similarly to the above, the inspection may be carried out as to the electric connection through the tentative adhesion after the step (ii) and before the step (iii), and only when the electric connection has proved to be good, the step (iii) may be carried out. Also similarly to the above, when the electric connection has proved to be bad, said other wiring board element or the surface mount device may be removed and a fresh wiring board element or surface mount device may be prepared and then the step (ii) is carried out. Alternatively, the wiring board element may be removed and replaced.

In the above production process of the product wiring board as described above, it is possible that the connector sheet is connected to the wiring layer of the wiring board element, and a second electric member different from said other electric member (i.e. the first electric member) which is connected in the above production process is connected to the connector sheet, so as to form another circuit pattern of the second electric member and the wiring layer of the wiring board element different from the circuit pattern which is formed from the wiring layer of the wiring board element and the first electric member. That is, the connector sheet according to the present invention is used not only for connecting the wiring layer of the wiring board element to a given other electric member but also for changing the circuit pattern to a different circuit pattern by changing the electric member (such as the first electric member), to be connected by the connector sheet to other electric member (such as the second electric member).

The connector sheet according to the present invention comprises the sheet substrate and a plurality of the electrically conductive members which pass through the sheet substrate wherein the front surface and the rear surface of the sheet substrate has the tackiness under the first condition and the adhesiveness under the second condition, so that repairing is possible, namely the inspection can be carried out under the tentative adhesion condition, after which the electric member (or the wiring board element including such electric member) which is tentatively adhered to the connector sheet may be replaced with a fresh electric member (or a fresh wiring board element including such electric member). Also such connector sheet provides a connecting member which is adaptable to the narrow wiring pitch. Further, using the connector sheet according to the present invention provides a useful method of electrically connecting the wiring board element and also a production process of the product wiring board (or module) comprising the wiring board element.

According to the present invention, when the connector sheet having the wiring layer is connected to a portion of a surface (or side) of the wiring board element, the multi-layered wiring board as a product wiring board can be readily produced which has a part where the number of wiring layers is larger compared with the other part, and the wiring layer(s) of the former part may have a high wiring density and narrow a wiring pitch. As a result, the product wiring board having the wiring layer(s) with the high wiring density and fine wiring pitch can be produced inexpensively.

### BRIEF DESCRIPTION OF DRAWINGS

FIG. 1 shows in a schematic cross sectional view, a connector sheet 100 of Embodiment 1 according to the present invention;

FIG. 2 shows in a schematic perspective view, the connector sheet 100;

FIGS. 3(a) to 3(c) each shows in a schematic cross sectional view, a step of a method of electrically connecting wiring boards while using the connector sheet 100;

FIGS. 4 shows in a schematic cross sectional view, a connector sheet 101 of Embodiment 2 according to the present invention;

FIGS. 5 shows in a schematic cross sectional view, another connector sheet 102 of Embodiment 2 according to the present invention;

FIGS. 6 shows in a schematic cross sectional view, a further connector sheet 103 of Embodiment 2 according to the present invention;

FIGS. 7(a) to 7(c) each shows in a schematic cross sectional view, a step of a method of electrically connecting wiring board elements while using the connector sheets 100 and a spacer substrate 400;

FIGS. 8(a) to 8(c) each shows in a schematic cross sectional view, a step of a method of electrically connecting a surface mount device and a wiring board element while using the connector sheets 100;

FIGS. 9 shows in a schematic cross sectional view, a multi-layered wiring board 2100 of Embodiment 4 according to the present invention;

FIG. 10 shows in a schematic cross sectional view, a connector sheet 2010 of Embodiment 4 according to the present invention;

FIGS. 11(a) to 11(c) each shows in a schematic cross sectional view, a step of a process of producing the connector sheet 2010;

FIGS. 12(a) and 12(b) each shows in a schematic cross sectional view, a step of a process of producing the connector sheet 2010 which includes a passive part (2044a, 2044b);

FIG. 13 shows in a schematic cross sectional view, a variation of the multi-layered wiring board 2100 of Embodiment 4 according to the present invention;

FIG. 14 shows in a schematic cross sectional view, a further variation of the multi-layered wiring board 2100 of Embodiment 4 according to the present invention;

FIGS. 15(a) to 15(c) each shows in a schematic cross sectional view, a step of a process of producing a multi-layered wiring board (or module) 2100 of Embodiment 5 according to the present invention;

FIG. 16 shows in a schematic cross sectional view, a configuration of a glass/epoxy resin wiring board 2500 of the prior art;

FIG. 17 shows in a schematic cross sectional view, a configuration of a glass/epoxy resin multi-layered wiring board 2510; and

FIG. 18 shows in a schematic cross sectional view, a configuration of a buildup wiring board 2520.

In the drawings, reference numbers denote the followings:
10, 11 . . . sheet substrate, 11′ adhesive layer,
12, 13 . . . tacky layer, 20 . . . conductive member,
30 . . . release film, 40 . . . sheet substrate,
100, 101, 102, 103 . . . connector sheet, 210 . . . wiring board,
220 . . . flexible wiring board,
310, 311. 311′ . . . electronic part, 400 . . . spacer substrate,
510, 520 . . . multi-layered wiring board,
530 . . . surface mount device, 540 . . . space,
550 . . . multi-layered wiring board, 2010 . . . connector sheet,
2012 . . . sheet substrate, 2014 . . . conductive member,
2016 . . . wiring layer, 2018 . . . release film,
2020 . . . core wiring board, 2030 . . . electronic part,
2032 . . . semiconductor element, 2034 . . . passive part,
2040 . . . carrier sheet, 2044a . . . resistor element,
2044b . . . capacitor, 2050 . . . insulation layer,
2051 . . . wiring layer, 2052 . . . through hole,
2053 . . . plated layer, 2054 . . . wiring layer, 2055 . . . laminate,
2056 . . . via hole, 2060 . . . insulation layer,
2061 . . . wiring layer, 2062 . . . via hole,
2100 . . . multi-layered wiring board,
2500, 2510 . . . glass/epoxy resin multi-layered wiring board,
2520 . . . buildup substrate

### DETAILED DESCRIPTION OF THE INVENTION

Embodiments of the present invention will be explained with reference to the accompanying drawings. It is noted that the present invention is not limited to those embodiments, and also that any combination of two or more of the following embodiments may be appropriately combined.

### EMBODIMENT 1

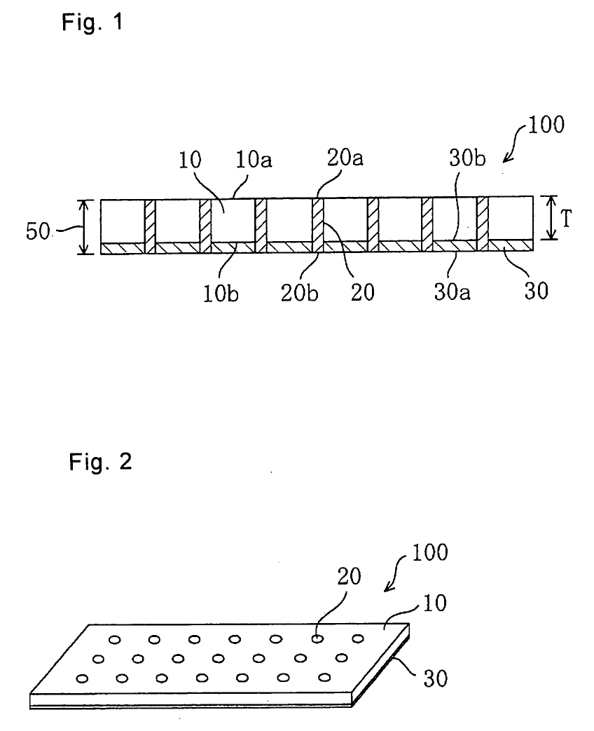

The connector sheet of Embodiment 1 according to the present invention is explained with reference to FIGS. 1 and 2. FIG. 1 schematically shows a cross-sectional view of the connector sheet 100 of this embodiment, and FIG. 2 schematically shows a perspective view of such connector sheet 100.

The connector sheet 100 of the shown embodiment includes a sheet substrate 10 and a plurality of conductive members 20. Each of the front surface 10a and the rear surface 10b of the sheet substrate 10 has the tackiness under the first condition. Under “the first condition”, the curing reaction of the thermoset resin of the front surface 10a and the rear surface 10b is not completed (and therefore the curing reaction may proceed, but does not reach the so-called C-stage state), so that the adhesiveness as described above and below is not developed. Preferably, under the first condition, no curing reaction occurs (or proceeds). As a result, the first condition ensures the tackiness of the surfaces which allows the tentative adhesion, and such tackiness does not leads to the permanent adhesion as will be described below. When an atmosphere is considered in which the connector sheet is practically used, such first condition includes a room temperature condition or room temperature range composition (for example, a temperature range of which lower limit is one of about 10° C., 15° C., 20° C. and 25° C. and of which upper limit is one of about 30° C., 35° C. and 40° C., such as 10° C. to 40° C., 15° C. to 35° C., 20° C. to 30° C. or the like). It is preferable that the tackiness increases when the temperature increases, provided that the curing reaction of the thermoset resin is not completed and preferably provided that the curing reaction does not occur. For example, it is particularly desirable that the tackiness is still kept even at a temperature which is higher than about 40° C., particularly higher than about 50° C.

Most preferably, the first condition comprises a temperature or a temperature range between about 0° C. and about 80° C. Concretely, such temperature or temperature range is between 30° C. and 60° C., and the temperature range is for example between 30° C. and 60° C. It is noted that since the tackiness is to be kept, a period for which the thermoset resin is subjected should not be so long as a period which results in the completion of the curing reaction when such temperature or temperature range allows the curing reaction to proceed. In this case, the first condition therefore further includes the period for which the thermoset resin is subjected to such temperature or temperature range.

Each of the conductive members 20 extends along a thickness direction 50 of the sheet substrate 10 so that it passes through the sheet substrate 10. Such extension of the conductive members makes electric conductivity of the sheet substrate along the thickness direction 50 different from that along a different direction (for example, a spreading direction of the sheet substrate). As shown in FIG. 1, one end 20a of the conductive member 20 is located (namely, exposed) at the front surface 10a of the sheet substrate 10, while the other end 20b is located at the rear surface 10b, so that electric conduction is ensured between the front surface 10a and the rear surface 10b.

It is noted that FIG. 1 show an embodiment wherein the end surface of the conductive member 20 is substantially flush with the surface of the sheet substrate 10, but the present invention is not limited to such embodiment. For example, the end portion of the conductive member may protrude above or retracted from the surface of the sheet substrate 10.

The front surface 10a and the rear surface 10b of the sheet substrate 10 have the tackiness under the first condition, and develop the adhesiveness under the second condition which is different from the first condition. The “second condition” comprises the condition which allows the material (or the thermoset resin) forming the front surface 10a and the rear surface 10b to cure so as to provide the adhesiveness described below, preferably to provide the completion of the curing reaction. Concretely, the condition which allows the curing reaction includes the temperature not lower than a temperature at which the curing reaction starts, and such temperature may be appropriately determined depending on the material used for the formation of the front surface and the rear surface of the sheet substrate 10. It is noted that the condition under which the curing reaction starts but does not reach the completion of the curing reaction (so that the adhesiveness is reached) is included by the first condition. For example, the first condition includes the condition of a temperature (which allows the curing reaction to proceed) in combination with a period (which is too short to complete the curing reaction) which leads to the development of only the tackiness because the progression extent of the curing reaction is small.

The tackiness in the present specification is a term which is confronted with the general permanent bonding which corresponds to the adhesiveness in the present specification. One feature of the tackiness is that a bonding state can be achieved by the application of a small pressure for a short period at a normal temperature or a temperature a little higher than such temperature (for example, up to 80° C.) without using for example water, a solvent, heat or the like. Also, since the tackiness has a cohesive force and an elasticity, it allows the connector sheet to be removed with a small force from for example a rigid flat surface while the tackiness provides a relatively large bonding strength. After the removal, the tackiness again allows the connector sheet to adhere to the other object without any additional treatment such as a thermal treatment or a chemical treatment. As explained, the tackiness means a property which allows the connector sheet to adhere with a small pressure and also to be removed by the application of a small force (for example, a force not larger than 400 g/cm as a peel strength), and such tackiness is also expressed herein by using a phrase “tentative adhesion” expediently. On the other hand, the adhesiveness means a state where two surfaces are combined together by means of a chemical and/or physical force so that two or more members are integrated by means of the adhesiveness. In the present specification, the adhesiveness is a term which is confronted with the general tentative bonding which corresponds to the tackiness in the present specification. The adhesiveness means a permanent bonding or a state wherein two members in the integrated condition can be separated into each separate member with a very strong force (for example, a force larger than 700 g/cm as a peel strength). Such adhesiveness is also expressed herein by using a phrase “permanent adhesion” expediently.

In the connector sheet according to the present invention, a peel strength of a connector sheet having a size of a 10 mm width and a 50 mm length is used as a quantitative measure for the tackiness and the adhesiveness. The tackiness of the connector sheet according to the present invention corresponds to a peel strength preferably in the range between 10 g/cm and 500 g/cm and more preferably in the range between 100 g/cm and 400 g/cm. That is, the connector sheet has such peel strength as the adhesiveness. When the peel strength is excessively small, detachment of the connector sheet happens during for example the inspection or the transportation of a wiring board element which includes the tentatively adhered connector sheet. When the peel strength is excessively large, intentionally peeling the connector sheet becomes difficult.

The adhesiveness of the connector sheet according to the present invention corresponds to a peel strength preferably not smaller than 700 g/cm and more preferably not smaller than 1000 g/cm or more, or corresponds to a state which leads to material failure of the connector sheet itself or a member which is connected by the connector sheet. That is, the connector sheet has such peel strength or such state as the adhesiveness. The peel strength not smaller than 700 g/cm provides the electrical connection having high reliability even with a large stress which may be applied to a product wiring board during for example its transportation or application.

The above explained peel strength is measured by a peel strength measuring method according to JIS K6850. Practically, a connector sheet is placed between a rigid substrate and a flexible substrate both having the same size, and then these substrates are adhered together through the connector sheet by applying a small force to them. The connector sheet has a size of a 10 mm width and a 50 mm length. The rigid substrate has a size of a 100 mm width and a 100 mm length, which substrate is a cured (679 F) CCL (copper clad laminate) of a glass/epoxy resin substrate (thickness: 1.6 mm) commercially available from Hitachi Chemical with its copper foil removed entirely through etching. The flexible substrate is a polyimide film substrate without a wiring layer commercially available from Nippon Mektron, Ltd. and it is made of a polyimide film having a thickness of 25 μm which has a cover layer of the same polyimide film having a thickness of 25 μm on each sides of the former polyimide film. Then, the rigid substrate is fixed. Thereafter, a tensile force is applied to the flexible substrate with an angle of 90° relative to the rigid substrate until the flexible substrate is peeled off from the connector sheet. The peel strength is defined as a tensile force per unit length of the connector sheet when such peeling off occurs.

The number of the conductive members per unit area (1 cm²) of the front (or rear) surface 10a (or 10b) of the sheet substrate 10 may be for example 1000 or more. For example, the number is in the range between 400 and 2500 per one square centimeter of the surface. The shown conductive members 20 may be formed by preparing through holes through the sheet substrate 10 and then filling the through holes with an electrically conductive paste. The conductive paste comprises, for example, a liquid thermoset resin and a conductive metal powder. The conductive members 20 may be formed by the other manner such as insertion of metal rods or embedding metal balls as far as the electric conduction is ensured along the thickness direction of the sheet substrate. The shape of the conductive members (especially, a shape of their exposed end surfaces) is not particularly limited, and it may be for example a circle. The other shape such as an oval, a rectangle, a square and the like may be possible in the shown embodiment, the shape of the conductive members is a circle of which diameter is about 0.05 mm to 0.2 mm, and of which pitch is about 0.1 mm to 0.5 mm.

When the conductive paste is used for the conductive member 20, the conventional paste may be used. For example, it is preferable to use a conductive paste which contains a metal filler conferring the conductivity, a liquid epoxy resin having at least two epoxy groups per one molecule contributing to the mechanical bonding, a latent curing agent and a small amount of a solvent.

By appropriately selecting the metal filler in the conductive paste and appropriately including the solvent in the conductive paste, the conductive members develops the electric conductivity under the first condition after filling the conductive paste into the through holes. The conductive paste generally comprises the metal filler, the epoxy resin and the curing agent as described below.

The metal filler is required to be present in the conductive paste at a high concentration. This is because the conductive members should have a low resistance, and the conduction reliability should be ensured even though the connector sheet is bent due to ambient heat or a mechanical stress. When a size of the particulates of the metal filler is too large, it is difficult to achieve the low resistance and the reliability. On the other hand, when the size is too small, a specific surface area of the filler becomes large which results in an increased viscosity of the paste, so that printing of the paste for filling the through holes becomes impossible. In order that contact probability of the filler is large even after filling the paste, preferably copper powder and more preferably silver coated copper powder is used as the metal filler. The silver coated copper powder comprises a copper core and a relatively soft silver coating around the core, which provides sufficient electric connection through silver even after the filling.

When the electric connection is achieved by the copper powder, powder particles are in point-contact with each other since copper is relatively hard. On the other hand, when the connection is achieved with silver powder, a contact area between the powder particles is relatively large since silver is relatively soft, which provides the better electric connection. However, such contact between the silver particles is likely to be disengaged if a force is applied from the outside because such connection is of merely physical contact between the powder particles. Contrary to this, since the copper powder is relatively hard, such disengagement is more unlikely because of its hardness. The silver coated copper powder makes use of advantages of silver and copper. Namely, copper functions to provide a suitable hardness while silver functions to enlarge the contact area between the particles. When the connector sheet is tentatively adhered to an object by means of the tackiness wherein such silver coated copper powder is used for the conductive members, the electric connection is achieved by the silver coated copper powder. This is one of reasons why the pressure is applied when the inspection of the electric connection state is carried out as described above.

Further, such paste provides complete curing of the resin under the second condition as well as the electric connection with a low resistance. When the silver coated copper powder is used as the metal filler and dispersed in the conductive paste at its large content, an average size (or diameter) of the filler is preferably in the range between 0.5 μm and 20 μm and its specific surface area is preferably in the range between 0.1 m²/g and 1.5 m²/g, more preferably between 0.1 m²/g and 1.0 m²/g.

When the conductive paste includes a small amount of the solvent, evaporation of such solvent under the first condition leads to a relatively higher content of the filler, which increases the contact probability of the filler. Further, the addition of the solvent reduces the viscosity of the conductive paste, so that the paste becomes suitable for continuous printing. For example, as such solvent, a solvent having a low boiling point such as butyl acetate, isopropyl alcohol an the like may be used. It is preferable that the paste contains 0.1% to 2% by weight of the solvent. When the content is smaller than 0.1% by weight, the content increase of the metal filler due to the solvent evaporation is not so remarkable. When the content is larger than 2% by weight, a ratio of the metal filler in the conductive paste is excessively small so that sufficient electric connection may be impossible.

The conductive paste preferably contains a liquid epoxy resin having at least two epoxy groups per one molecule. When a one-component type conductive paste without a solvent (or with a solvent in its small amount) is prepared, a liquid epoxy resin is basically necessary as an epoxy resin component. In order to disperse the above explained metal filler at a high concentration in the paste, the epoxy resin preferably has a viscosity of not larger than 1.5 Pa.s. When the epoxy resin has a larger viscosity, the viscosity of the conductive paste increases greatly. When the viscosity of the epoxy resin exceeds 200 Pa.s, filling the through holes with the paste becomes very difficult.

As the epoxy resin as mentioned above, for example the following may be exemplified: a bisphenol A type epoxy resin, a bisphenol F type epoxy resin, an alicyclic epoxy resin, an amine type epoxy resin, and a liquid epoxy resin having at least two epoxy groups per one molecule. In order to reduce a volatile content, a liquid epoxy resin which has been subjected to a vacuum distillation treatment may be used. Particularly, an epoxy resin formed by glycidyl esterification of a dimer acid has a low viscosity and also a cured material therefrom has an elasticity which provides an improved stress relaxation effect. Thus, when the such epoxy is contained in 10 parts or more parts by weight together with other epoxy resin(s) (90 parts or less parts by weight), the reliability of the conductive members is improved.

As to the curing agent, any of the conventional ones may be used. Typically, an amine based curing agent (such as dicyanamide, carboxylic acid hydrazide), a urea based curing agent (such as 3-(3,4-dichlorophenyl)-1,1-dimethylurea), an acid anhydride based curing agent (such as phthalic anhydride, methylnadic anhydride, pyromellitic anhydride, hexahydrophthalic anhydride), and an aromatic amine based curing agent (an amine adduct curing agent) (such as diaminophenylmethane, diaminodiphenylsulphon) may be used. It is desirable to use a solid latent curing agent so as to avoid curing of the liquid epoxy resin during a low temperature treatment of the conductive paste.

In the connector sheet according to the present invention, when the conductive members contains the thermoset resin, what are explained above as to the curing reaction of the thermoset resin of the front surface and the rear surface of the sheet substrate are also applicable to the curing reaction of the thermoset resin of the conductive members. That is, it is particularly preferable under the first condition that the curing reaction of the thermoset resin of the conductive paste does not occur. Even though the curing reaction occurs, it is important that the curing reaction does not proceed excessively, namely the curing reaction is not completed. It is noted that the curing reaction is completed under the second condition.

In this embodiment, a release film 30 is placed on at least one of the front surface 10a and the rear surface 10b of the connector sheet 100. The shown embodiment has the release film 30 on the rear surface 10b. The release film 30 makes handling of the connector sheet 100 easier. When the release film 30 is present, the connector sheet 100 may be transferred, stacked or converted into a roll form without minding the tackiness of the connector sheet. Further, only peeling off the release film 30, the tackiness of the sheet substrate 10 of the connector sheet is ready for its use. The release film may be made of for example a polyethylene (PE), a polyethylene terephthalate (PET), a polyphenylene sulphide (PPS), or a polyethylene-naphthalate (PEN).

It is noted that the connector sheet of the embodiment shown in FIG. 1 has the release film 30 on its one side, but may have the release film on its each side. Further, in the shown embodiment, the rear surface 30b of the release film 30 is in contact with the rear surface 10b of the sheet substrate 10, and the front surface 30a of the release film 30 may be in contact with the front surface 10a of the sheet substrate 10 when the connector sheet 100 is transformed into a roll form or a plurality of the connector sheets are stacked.

A thickness T of the sheet substrate 10 is for example in the range between about 20 μm and about 100 μm, and may be in the range between about 25 μm and about 50 μm in the shown embodiment. A thickness of the release film is for example in the range between about 12 μm and about 25 μm. Since the release film 30 is finally removed, the conductive members 20 may be formed such that they pass through the release film also as shown in FIG. 1, or they pass through only the sheet substrate 10 not through the release film 30. When the conductive members 20 pass through the release film 30, the end portions of the members 20 protrude from the surface of the sheet substrate 10 by a distance which corresponds to the thickness of the release film 30.

In the embodiment shown in FIG. 1, the sheet substrate 10 may be made of for example a silicone resin, an epoxy resin (as a thermoset resin) and an inorganic filler. Thus, the front surface 10a and the rear surface 10b of the sheet substrate contains the thermoset resin. The silicone resin contributes mainly to the tackiness, the epoxy resin contributes mainly to the adhesiveness, and the inorganic filler contributes to control (or harmonization) of thermal expansion coefficients after the permanent adhesion. The inorganic filler is made of for example Al₂O₃, SiO₂, MgO. or the like. There may be an embodiment wherein no inorganic filler is used.

Further, the inorganic filler may be made of BN, AIN and the like. The inclusion of the inorganic filler allows, in addition to the thermal expansion coefficient, various properties of the connector sheet to be controlled or harmonized. When Al₂O₃, BN, or AIN is included, the thermal conductivity of the connector sheet is improved, so that heat transfer between the wiring board elements connected through the connector sheet may be accelerated.

When the thermal expansion coefficients of the wiring board elements to be connected through the connector sheet are different from each other, a stress may be created between the elements, which results in the failure of the connection between the elements. However, when the inorganic filler for the connector sheet is appropriately selected, the thermal expansion coefficient of the connector sheet may be controlled to be intermediate between the thermal expansion coefficients of the elements. Concretely, since the thermal expansion coefficient of the resin is large, the addition of the filler of SiO₂, Al₂O₃ or the like and/or the adjustment of an amount of the filler to be added make the thermal expansion coefficient smaller. Optionally, when the filler of MgO is added, the thermal conduction as well as the thermal expansion coefficient is increased. Further, the inclusion of the filler of SiO₂, particularly amorphous one reduces the thermal expansion coefficient and leads to a light connector sheet of which dielectric constant is smaller, so that such connector sheet may be used for the formation of the connection in a high speed circuit (or high frequency circuit) having a less signal loss.

There is no limitation as to a ratio of the silicone resin, the thermoset resin and the inorganic filler as far as the above mentioned combination of the tackiness and the adhesiveness. For example, the sheet substrate of the connector sheet according to the present invention contains 100 parts by weight of the epoxy resin, 10 to 30 parts by weight of the silicone resin, and 30 to 100 parts by weight of the inorganic filler.

Since the connector sheet 100 (particularly, of which the front surface 10a and the rear surface 10b of the sheet substrate 10) has to have the tackiness when the connector sheet 100 is tentatively adhered to an object, it is preferable that the tackiness is developed at a room temperature, which is more usual condition. It is also possible that the connector sheet 100 is tentatively adhered to at a temperature other than or higher than the room temperature so as to increase the tackiness, it is more preferable that the tackiness of the connector sheet 100 is developed in a temperature range between 15° C. and 30° C., preferably between 10° C. and 50° C. and more preferably between 0° C and 80° C. When the tentative adhesion is not carried out at a low temperature, the tackiness does not have to be developed at such low temperature which is lower than the room temperature, so that it is sufficient that the tackiness is developed at a temperature or in a certain temperature range between the room temperature and 80° C. Further, when the tentative adhesion is not carried out at a high temperature, the tackiness has to be considered only at a temperature around the room temperature or between the room temperature and a temperature a little higher than the room temperature, so that such high temperature has not to be considered as to the development of the tackiness.

The adhesiveness of the connector sheet 100 is developed under the second condition, that is, when the curing reaction of the material which forms the sheet substrate occurs and completes. In the above mentioned combination materials (a) to (c), when a certain epoxy resin is used as the thermoset resin, heating to a temperature of not lower than for example 120° C. which is higher than its curing reaction starting temperature starts the curing reaction, which is thereafter completed whereby the connector sheet 100 provides the above explained adhesiveness. Therefore, the temperature of 120° C. or higher forms the second condition. The first condition under which such epoxy resin shows the tackiness is for example the room temperature or a temperature or a certain temperature range between the room temperature and 80° C. which is different from the second condition of 120° C. or higher. Thus, when those conditions are used separately depending on purposes (i.e. the tentative adhering and the permanent adhering), the tackiness and the adhesiveness are effectively utilized respectively.

One concrete example of the material which forms at least the front surface and the rear surface of the sheet substrate of the connector sheet 100 is for example a resin composition which comprises a thermoset resin as a main component which is in a liquid state at a room temperature, a thermoplastic resin and a latent curing agent wherein the thermoplastic resin is in the form of powder when the thermoset resin is in its uncured state. In such resin composition, the thermoplastic resin absorbs a small amount of the liquid thermoset resin and thereby swells under the first condition, so that the thermoplastic resin exhibits the tackiness and such tackiness is kept with the thermoset resin in the uncured state. Further, when the resin composition is heated to be in the second condition higher than a temperature at which the latent curing agent is activated, the curing reaction occurs and finally completes to develop the adhesiveness. As seen, the tackiness of the resin composition can be used under the first condition, and also the adhesiveness can be ensured by shifting the first condition to the second condition.

As the thermoset resin is in the liquid state at a room temperature, a liquid epoxy resin, a liquid polyphenol resin and the like may be used. Among them, the liquid epoxy resin is particularly preferable from viewpoints of its electric insulation property. Such liquid epoxy resin includes for example a bisphenol A type epoxy resin, a bisphenol F type epoxy resin, a bisphenol AD type epoxy resin, and a phenol novolak type epoxy resin.

As the latent curing agent, any known agent may be used depending on the kind of the thermoset resin to be used. For the liquid epoxy resin, for example the following may be used: a dicyandiamide based curing agent, a urea based agent, an organic acid hydrazide based curing agent, a polyamine salt based curing agent and an amine adduct based curing agent.

The thermoplastic resin powder is not particularly limited as far as it absorbs and swells a liquid component which is contained in the resin composition including the liquid thermoset resin as a main component. Practically, depending on the thermoset resin to be used, an appropriate thermoplastic resin which swells may be selected. With the liquid epoxy resin, a polyvinyl chloride, a polymethyl methacrylate, a polyethylene and a polyamide may be used. Particles which form the thermoplastic resin powder preferably have an average diameter in the range between 1 and 100 μm.

One example of the resin composition for at least the front surface and the rear surface of the sheet substrate of the connector sheet contains 60 to 85 parts, preferably 70 to 80 parts by weight of the thermoset resin (including the curing agent) and 2 to 10 parts, more preferably 4 to 6 parts by weight of the thermoplastic resin based on 100 parts by weight of the resin composition.

The resin composition may optionally contain an additive such as a coupling agent, a dispersing agent, a coloring agent, a release agent and the like, so that a property of the sheet substrate as an insulation layer may be improved. For example, the coupling agent improves adhesion of the inorganic filler to the insulation resin, and therefore the isolation voltage. The dispersing agent improves the dispersion of the inorganic filler so that more uniform distribution of the inorganic filler is achieved in a thermally conductive sheet substrate. Further, carbon powder as the coloring agent improves the heat dissipation of the sheet substrate.

Other concrete example of the resin composition for the sheet substrate for the connector sheet 100 comprises at least a thermoset resin as a main component, a silicone resin and a latent curing agent. As to this resin composition, the curing reaction of the thermoset resin is not completed (for example in the semi-cured condition), preferably in a uncured condition under the first condition, so that the tackiness that the silicone resin has may be used, and the curing reaction of the thermoset resin proceeds and completes under the second condition achieved by heating so that the adhesiveness of the cured thermoset resin may be developed. The silicone resin distributed in the composition may allow its curing reaction to develop tackiness, but such tackiness does not adversely affect the adhesiveness of the thermoset resin after the completion of the curing reaction. One example of such resin composition for the sheet substrate of the connector sheet contains 30 to 75 parts, preferably 50 to 70 parts by weight of the thermoset resin (including the curing agent) and 2 to 20 parts, preferably 5 to 10 parts by weight of the silicone resin based on 100 parts by weight of the resin composition.

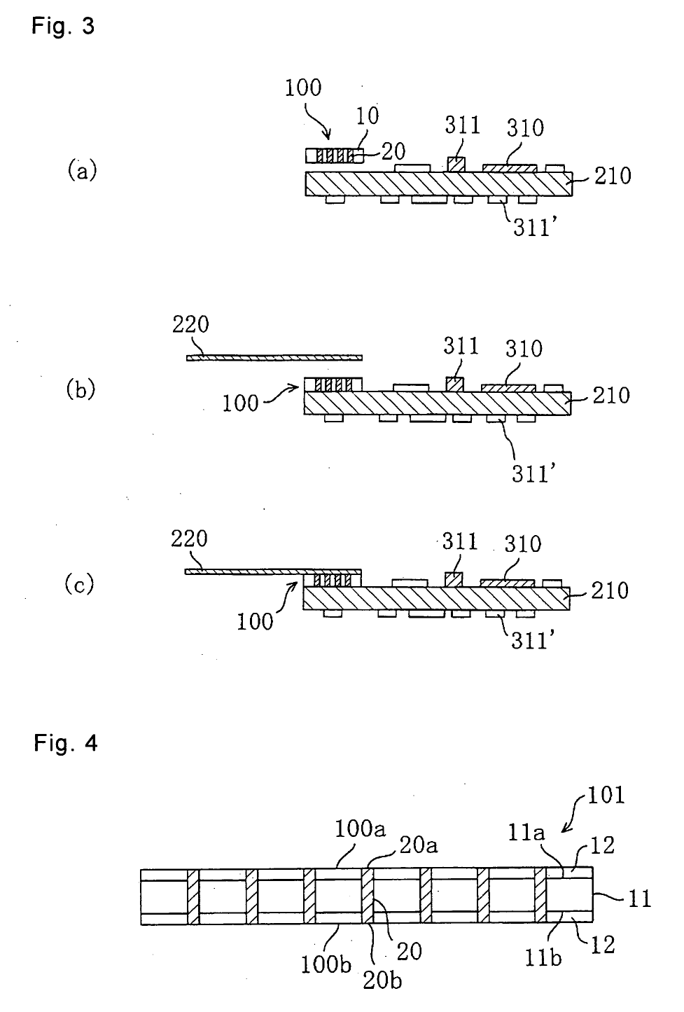

Then, a method wherein a wiring board element is electrically connected by using the connector sheet 100 with reference to FIGS. 3(a) to 3(c) is explained.

First, as shown in FIG. 3(a), the connector sheet 100 according to the present invention is placed above a wiring board (which corresponds to the wiring board element) 210 onto which electronic parts (310, 311 and 311′) are mounted. The connector sheet 100 has the tackiness under the first condition, and develops the adhesiveness under the second condition as described above. The connector sheet 100 comprises the sheet substrate 10 and the conductive members 20, so that it has the electric conductivity along a thickness direction of the connector sheet as it is, namely even without being compressed, which is different from the conventional anisotropic conductive film which requires to be compressed so as to develop its thickness direction conductivity.

In the embodiment shown in FIG. 3(a), the wiring board 210 is a so-called rigid board (for example, a usual printed circuit board), on which a wiring layer (not shown) is formed as a wiring pattern for a circuit. The electronic parts (310, 311 and 311′) are electrically connected to such wiring layer. The electronic part 310 is for example a semiconductor chip (such as a surface mount IC device), and the electronic parts 311 and 311′ are for example surface mount devices (such as a chip capacitor, a chip inductor, a chip resistor and the like).

Then, as shown in FIG. 3(b), the connector sheet 100 is lightly pressed on a predetermined position of the wiring board 210 under the first condition so that the connector sheet 100 is tentatively adhered to the wiring board 210 by means of the tackiness of the connector sheet. The first condition is for example a predetermined temperature in the range between a room temperature and 80° C. (for example the room temperature). The electric conductivity between the front surface (or top surface) and the rear surface (or bottom surface) of the connector sheet 100 is ensured by the conductive members 20, and only such tentative adhesion of the connector sheet 100 to the wiring board 210 is sufficient and no compression of the connector sheet 100 is required so as to obtain the electric connection of the connector sheet with the wiring board. It should be noted that this does not mean the application of the compression is excluded from the present invention, and in some cases, the application of the compression is preferable.

Thereafter, a wiring board 220 (which also corresponds to other wiring board element) is prepared which is to be connected with the wiring board 210 through the connector sheet 100. As shown in FIG. 3(c), the wiring board 220 is placed above the connector sheet 100 and tentatively adhered to the connector sheet 100 under the first condition (which may be the same as or differed from the first condition for the tentative adhesion between the connector sheet 100 and the wiring board 210) similarly to the above (i.e. by means of the tackiness of the connector sheet), whereby the wiring boards 210 and 220 are temporarily fixed (thus tentatively adhered) to each other through the connector sheet 100 so that they are tentatively electrically connected with each other. The shown wiring board 220 is a flexible wiring board which is made of for example a polyimide film. The board 220 also has a wiring board (not shown), and may have an electronic part thereon if necessary.

Then, inspection is carried out in the embodiment shown in FIG. 3(c) as to the electric connection state between the wiring boards 210 and 220. The inspection may be carried out by measuring an electric resistance between the wiring board 210 and the wiring board 220. The measurement may be done automatically using for example a scanner and a multimeter. When the inspection indicates good connection state, temporarily fixed boards 210 and 220 are subjected to the second condition for example by raising an ambient temperature around the boards, so that the boards are permanently adhered whereby the wiring boards 210 and 220 are permanently electrically connected. The second condition comprises a predetermined temperature for example not lower than for example 140° C. (preferably in the range for example 150° C. to 170° C.). Under the second condition, the curing reaction of the connector sheet (in fact, the thermoset resin of the surfaces of the sheet substrate of the connector sheet) starts, and the adhesiveness is developed after a predetermined period so that the connector sheet functions as an adhesive. Therefore, the wiring boards 210 and 220 are permanently fixed in contrast to the tentative adhesion by means of the tackiness.

It is noted that during the inspection of the electric connection state between the board 210 and 220, the wiring board 220 is preferably pressed toward the wiring board 210 using a pressing tool having a size which is the same as that of the connector sheet, which allows more accurate inspections as to the electric connection state. The conductive members 20 of the connector sheet tentatively adhered between the boards 210 and 220 may be insufficiently connected to the wiring boards because of effects of the warpage of the boards and/or the thickness variation in the wiring layer formed on the boards. Such insufficient connection may be determined as failure of the electric connection. Therefore, pressing the boards as mentioned above so as to compress the connector sheet suppresses the effects of the warpage and the thickness variation by absorbing them, so that more accurate inspection becomes possible. The pressure applied to the surface of the connector sheet may be about 0.05 MPa to 3 MPa and preferably about 0.1 MPa to 1 MPa. It is sufficient that the application of the pressure is carried out only during the inspection. However, it may be carried out (but not necessarily carried out) also after the inspection. Thus, for example, the application of the pressure is not necessarily required during, for example, transportation of the tentatively connected wiring boards or after the boards are tentatively adhered to the connector sheet.

When the inspection indicate the failure of the electric connection state, at least one of the wiring boards 210 and 220 is removed from the connector sheet 100 under the first condition so that the tentative adhesion is released between the connector sheet and at least one of the wiring boards 210 and 220. Under the first condition, the connector sheet is in the tentative adhesion state, so that such adhesion can be released by the application of a peeling force which is larger than the peel strength of the connector sheet corresponding to the tentative adhesion. Thus, when the inspection indicates the failure, repair (i.e. replacement of members) can be readily carried out.

It is noted that with the conventional anisotropic conductive film, the electric conductivity inspection becomes possible only after such film is completely connected to a wiring board by thermocompression. Therefore, even though the inspection indicates the failure of the electric connection state, no repair is possible. That is, there is no way other than disposing the connected boards 210 and 220 of which electric connection has the failure. Contrary to this, using the connector sheet 100 according to the present invention allows the repair, so that the number of disposed members (or parts) is greatly reduced, which leads to the cost reduction. Thus, using the connector sheet 100 according to the present invention, it becomes possible to provide a process of producing a product multi-layered wiring board with a less cost.

Even though the connection has proved to have the failure, if the wiring boards have no failure, the steps shown in FIGS. 3(a) to 3(c) can be carried out again so that a multi-layered wiring board having at least two wiring layer elements may be produced through the electrically connecting step of the wiring board elements followed by the inspection step thereafter.

When the connector sheet 100 is removed after the state shown in FIG. 3(c), it is possible to lower the temperature around the connector sheet 100 to a third condition which is lower than the temperature of the first condition, so that the tackiness of the connector sheet is reduced. Namely, since temperature decrease leads to the reduction of the tackiness, the temperature lowering may be used so as to readily remove the connector sheet. When the temperature at which the tentative adhesion of the connector sheet is carried out (i.e. the first condition) is a certain temperature for example between the room temperature and 80° C., a temperature lower than the room temperature (for example, a certain temperature less than 0° C., preferably in the range between −10° C. to −20° C.) may be employed as the third condition. By using the reduction of the tackiness of the connector sheet under the third condition (i.e. a further lower temperature), the connector sheet can be readily removed when the inspection indicates the failure of the electric connection state. Concretely, after the tentative adhesion is provided between the wiring boards 210 and 220 followed by the inspection, the boards tentatively adhered to connector sheet is stored for 20 seconds at a temperature of −15° C. in a refrigerator when the failure has been found through the inspection. Then, the boards are taken out of the refrigerator. The board 210 is readily peeled off from the connector sheet and also the board 220 is so. When the connector sheet is found to have the failure through the inspection, a fresh connector sheet may be used to connect the boards. In addition, it is also preferable to produce a connector sheet of which tackiness substantially disappears under the third condition which is lower than the first condition.

Since the connector sheet 100 according to the present invention comprises the sheet substrate 20, a space for the connector sheet which adversely affects the miniaturization of the device is almost not required, which is in contrary to the case in which the stacking connector is used. Further, the connector sheet is in the sheet form so that it is thin, which can contribute to the production of the thin devices. The shape and the area of the connector sheet 100 (i.e. an area of a surface of the connector sheet on which surface an object to be connected is located; an occupying area) are not particularly limited, but selected depending on a mounting area of the wiring board element, the wiring layer, the electronic part or the like (i.e. the electric member) to be connected. One example, the connector sheet 100 has a generally rectangle or circle shape and an area of, for example, 5 to 1000 mm².

Since the connector sheet can be adhered to the wiring board by means of the tackiness of the connector sheet, it can be readily attached even to a deformable object like a flexible wiring board. This is a great advantage when compared with the stacking connector which is not easily attached to the flexible wiring board.

In addition, in the connector sheet, the sheet substrate 20 is perforated to form the through holes, in which the conductive members are formed, so that thus formed conductive members are able to adapt to the narrow wiring pitch compared with using the stacking connector. Concretely, it is very difficult for the stacking connector to adapt to the narrow wiring pitch of not larger than 0.3 mm, but the connector sheet is able to sufficiently adapt to the narrow wiring pitch not larger than 300 μm (preferably between 100 μm and 300 μm and more preferably between 40 μm and 200 μm).

When the above explained ACF is used, the electric connection can be ensured only when it is connected and completely cured while being compressed as explained above, so that no inspection is possible on the way of the formation of the connection and therefore no repair is possible. On the other hand, with the connector sheet 100 according to the present invention, such repair impossibility issue occurs, and the repair can be done when the inspection on the way of the connection indicates the failure, whereby a yield of the multi-layered wiring board production can be improved.

When the solder material is used for making the connection, a temperature is required which is high enough to melt the solder material. With the connector sheet according to the present invention, the tackiness ensures the tentative adhesion with the wiring board, so that no heating is required for such adhesion. Thus, the treatment at a predetermined temperature between a room temperature and for example 80° C. is possible, whereby the tentative adhesion of the connector sheet can be carried out without a problem as to a wiring board which includes an electronic part (for example, a certain semiconductor IC device) susceptible to a high temperature which causes a defect to reduce a reliability of the part. The soldering connection has a limitation as to adapting to the narrow wiring pitch, but the connector sheet according to the present invention is able to adapt to a wiring pitch which is narrower than the wiring pitch that the soldering connection can maximally achieved. In addition, when more than two wiring layers are to be laminated using the solder connection, solder materials having various melting points have to be prepared so as to avoid re-melting of the already connecting solder material. To the contrary, with the connector sheet 100, such melting point issue does not have to be considered. In addition, since the connector sheet 100 contains no toxic substance or controlled substance such as lead, it is adaptable to the environmental issues.

Since the connector sheet 100 according to the present invention comprises the sheet substrate 10 which has the tackiness under the first condition and develops the adhesiveness under the second condition and the conductive members which pass through the sheet substrate 10, it is possible to carry out the repair during the production of the product wiring board or the electrical connection method between the wiring board elements, and also to adapt to the narrow wiring pitch.

It is noted that in this embodiment as well as the following embodiments which will be described below, the wiring board element to be connected is not limited to the double-sided layer wiring board as shown, and it may be any wiring board such as a multi-layered wiring board having more than two wiring layers, a single-sided layer wiring board or the like.

### EMBODIMENT 2

Although Embodiment 1 has explained the connector sheet 100 of which sheet substrate 10 is entirely made of the same material, the connector sheet according to the present invention basically functions as far as the front surface and the rear surface of the sheet substrate of the connector sheet have the tackiness under the first condition and also develop the adhesiveness under the second condition as described above. Thus, the connector sheet is not limited to the embodiment shown in FIG. 1, and it may have a configuration as shown in FIGS. 4 to 6.

As shown in FIGS. 4 to 6 for example, the sheet substrate of the connector sheet according to the present invention may be composed of plural kinds of materials and/or plural layers in place of a single sheet substrate 10 as shown in FIG. 1.

The connector sheet 101 shown in FIG. 4 comprises a sheet member 11 as a middle layer, and a tacky layer 12 placed on each of the front surface 11a and the rear surface 11b of the sheet member 11. It is noted that the sheet member 11 and the tacky layers 12 form the sheet substrate of the connector sheet 101. The conductive members 20 pass through the sheet member 11 and the tacky layers 12 along their thickness directions so that one ends of the conductive members are exposed at the front surface 100a of the connector sheet 101 (i.e. an exposed surface of the tacky layer 12) and the other ends are exposed at the rear surface 100b of the connector sheet 101 (i.e. an exposed surface of the other tacky layer 12).

The tacky layer 12 has the tackiness under the first condition (for example, at a room temperature or a predetermined temperature between a room temperature and 80° C.) and develops the adhesiveness under the second condition. Such tacky layers 12 may be made of the above described materials which are used for the sheet substrate 10, and therefore the tacky layers provide the front surface and the rear surface of the sheet substrate having the tackiness under the first condition and developing the adhesiveness under the second condition in the connector sheet according to the present invention. For example, the tacky layers may be made of a mixture of a thermoplastic resin and a thermoset resin. Such tacky layers 12 adhere to a front surface 11a and a rear surface 11b of the sheet member 11 under the first condition, and develop the adhesiveness under the second condition (for example, at a predetermined temperature not lower than 120° C., preferably a predetermined temperature between a 150° C. and 170° C.), so that the tacky layers are converted through completion of the curing reaction to an adhesive layers having the adhesiveness which layers permanently bond to the sheet member as well as objects to be connected. The sheet member 11 may be made of a thermoplastic resin film, and a polyimide film, a PPS film or the like may be used for the sheet member 11.

With the embodiment shown in FIG. 4, the steps shown in FIGS. 3(a) to 3(c) are carried out under the first condition using the tackiness of the tacky layer 12 so that the tackiness is used for the tentative adhesion. When the inspection in the step 3(c) state indicates pass, the assembly of the wiring boards (210 and 220) and the connector sheet 100 as shown in FIG. 3(c) is subjected to the second condition. Practically, the temperature of an atmosphere around the assembly is raised so that the tacky layers develop the adhesiveness. Then, the tacky layers 12 permanently adhere to the front surface 11a and the rear surface 11b of the sheet member 11. Simultaneously, the tacky layers 12, and thus the front surface 100a and the rear surface 100b of the connector sheet 101 develop the adhesiveness so as to substantially permanently connect the wiring boards such as the boards 210 and 220.

The connector sheet 101 shown in FIG. 4 may be modified such that the tackiness of the tacky layer 12 on the front surface side 100a and that of the rear surface side 100b are different. Using such different tackinesses, one of the wiring boards 210 and 220 can be preferentially removed from the connector sheet, which makes the wiring board removal simple.

When the different tackinesses are provided, the tacky layer 12 of the front surface side 100a is made of a material which is different from a material for the tacky layer 12 of the rear surface side 100b. For example, at least one component of the material for the tacky layer is replaced with other component so as to provide the different tackinesses. Alternatively, when components of the material for the tacky layer are the same, a composition of the material is changed.

As to the connector sheet 100 shown in FIG. 1, the sheet substrate 10 is entirely made of a single material. This means that the sheet substrate is formed as if the sheet substrate 100 contained a tacky material throughout the substrate, so that the front surface 10a and the rear surface 10b of the sheet substrate 10 have the tackiness. Therefore, with such connector sheet 100, it is relatively difficult to provide the different tackinesses. On the other hand, since such sheet substrate is a single sheet, the production process of such connector sheet is relatively simple, which leads to the advantage in the production cost of the connector sheet.

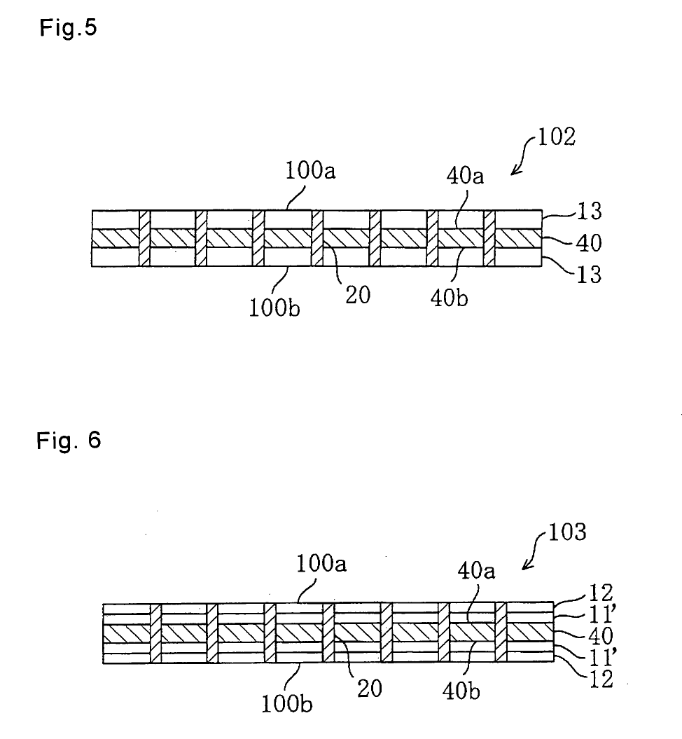

Next, embodiments shown in FIGS. 5 and 6 will be described. The connector sheets 102 and 103 shown in FIGS. 5 and 6 respectively comprises a sheet member 40 as the middle layer which is made of a completely cured material. The sheet member 40 is for example a woven fabric (including a knit) of an organic fiber or an inorganic fiber (such as a glass fiber), or unwoven fabric of an organic fiber (such as Aramid fiber) or inorganic fiber (such as a glass fiber) which fabric is impregnated with a thermoset resin which has been already cured.

The connector sheet 102 shown in FIG. 5 comprises the sheet member 40 on each side (40a or 40b) of which a tacky layer 13 is formed. The tacky layer 13 corresponds to the tacky layer 12 of the connector sheet 101 shown in FIG. 4, and it has the tackiness under the first condition and develops the adhesiveness under the second condition. The tacky layer 13 may be made of any of the above described materials (a) to (c). Also, the both tacky layers 13 may be made different materials so that the tacky layers, particularly the front surface 100a and the rear surface 100b have differential tackinesses respectively.

The connector sheet 103 shown in FIG. 6 corresponds to the embodiment shown in FIG. 4 except that the middle layer 11 in FIG. 4 is replaced with a sheet member 40 which includes an adhesive layer 11′ on each of the front surface 40a and the rear surface 40b of the sheet member 40. The adhesive layer 11′ functions to bond the tacky layer 12 to the sheet member 40. The tacky layer 12 of the connector sheet 103 shown in FIG. 6 is substantially the same as the tacky layer 12 of the connector sheet 101 shown in FIG. 4. The adhesive layer 11′ prevents the tacky layer 12 from being separated from the sheet member 40 when a wiring board is removed from the connector sheet under the first condition after the inspection. For such adhesive layer 11′, a thermoset resin such as an epoxy resin, a phenol resin and the like may be used.

In the embodiment, the sheet member 40 may be the same as that in the embodiment shown in FIG. 4 or 5. Therefore, the sheet member may be made of the above described thermoplastic resin film or woven or unwoven fabric. For example, when the sheet member 40 is made a polyimide film, sufficient strength and flexibility of the connector sheet are ensured. Further, if a flexible wiring board to be connected includes a polyimide film, a thermal expansion coefficient of the connector sheet can be made correspond to that of the flexible wiring board, which is advantageous.

The followings are examples of concrete thicknesses of the layers of the connector sheets shown in FIGS. 4 to 6:

Embodiment in FIG. 4
sheet member 11: 12 to 25 μm
tacky layer 12: 5 to 10 μm

Embodiment in FIG. 5
sheet member 40: 25 to 50 μm
tacky layer 13: 5 to 12 μm

Embodiment in FIG. 6
sheet member 40: 12 to 25 μm
adhesive layer 11′: 4 to 8 μm
tacky layer 12: 4 to 8 μm
   It is noted that any of the connector sheets 101, 102 and 103 may have the release film on at least one side thereof as in the case of the connector sheet 100.

### EMBODIMENT 3

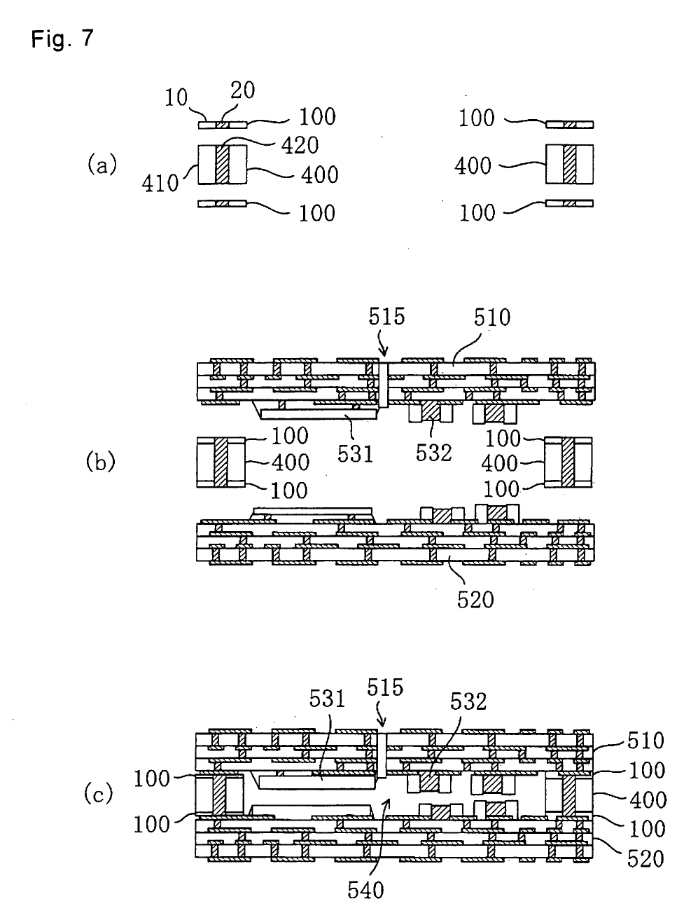

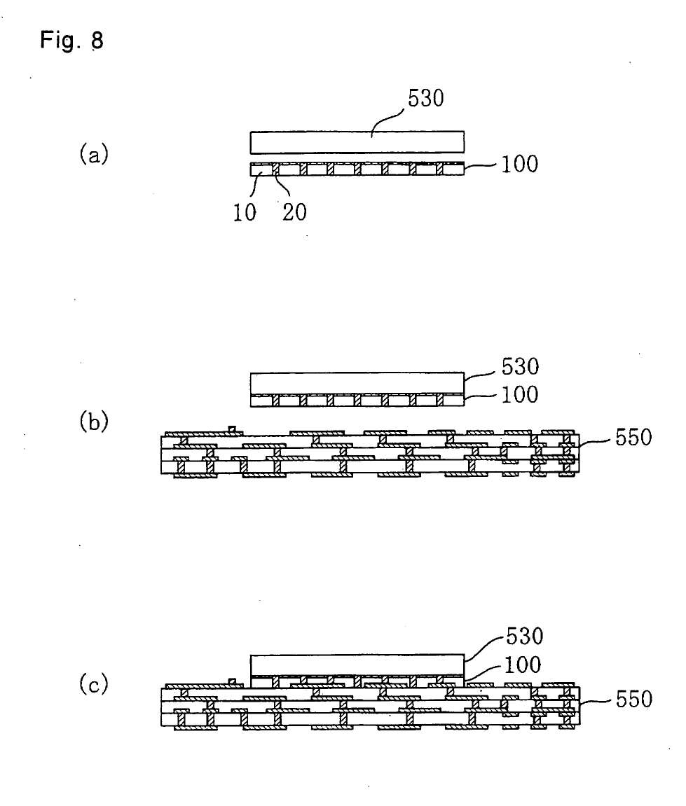

With reference to FIGS. 7 and 8, a process of connecting a wiring board while using the connector sheet according to the present invention will be described.

FIGS. 7(a) to 7(c) are schematic cross-sectional views which show the steps of the process wherein the connector sheet according to the present invention and a spacer substrate are used so as to electrically connect wiring board elements, whereby a product multi-layered wiring boar (or module) is produced.

First, the connector sheets 100 of Embodiment 1 and the spacer substrate 400 are prepared. The connector sheet 100 may be replaced with the connector sheet 101, 102 or 103 of Embodiment 2. The spacer substrate 400 functions to connect wiring boards (such as printed circuit boards) while keeping some spacing between the boards, and the shown spacer substrate 400 includes no electronic part. The shown spacer substrate 400 comprises a conductor such as a via hole conductor or wiring 420 which is located in the through hole passing through a substrate 410. For example, the substrate may be a glass/epoxy resin substrate, and the conductor may be formed by forming a plated through hole having a diameter of 0.1 mm followed by filling the through hole with a conductive resin.

Then, the connector sheets 100 are tentatively adhered to each of the top surface and the bottom surface of the spacer substrate respectively under the first condition, and thereafter such spacer substrate 400 is located between a first wiring board 510 (corresponding to the wiring board element as the electric member) and a second wiring board 520 (corresponding to other wiring board element as the electric member). The wiring boards 510 and 520 shown in FIG. 7(b) are multi-layered wiring boards on which electronic parts such as a semiconductor chip 531 and chip part 532 are mounted. It is noted that at least one of the wiring boards 510 and 520 may have a through hole 515 as shown.

Thereafter, the first wiring board 510 and the second wiring board 520 are electrically connected through the spacer substrate 400 and the connector sheets 100 placed on the both sides of the spacer substrate 400 respectively as shown in FIG. 7(c). That is, under the first condition, using the tackiness of the connector sheets, the first wiring board 510 is tentatively adhered to the upper connector sheet 100 and the second wiring board 520 is tentatively adhered to the lower connector sheet 100, so that a laminate comprising the wiring board elements is obtained.

After forming the configuration as shown in FIG. 7(c), inspection is carried out as to the electric continuity between the first wiring board 510 and the second wiring board 520. When the inspection indicates no problem, an atmosphere around the laminate is changed to be in the second condition, whereby the tentative adhesion through the connector sheets is converted to the permanent adhesion so that the configuration shown in FIG. 7(c) is fixed and a product multi-layered wiring board or a module is obtained. When the inspection indicates failure, the tentative adhesion state is disengaged so as to remove the spacer substrate from the wiring board. Then, any one or more, or each of the wiring boards without moving to the second condition, the spacer substrate and the connector sheets are checked, followed by carrying out the repair. When the wiring boards 510 and 520 and the spacer substrate have no problem and the connector sheet(s) has the failure, the connecting step with fresh connector sheets and the inspection step are carried out again so as to obtain the product wiring board.

With the product multi-layered wiring board of the embodiment shown in FIG. 7(c), the spacer substrates 400 and the wiring board 510 and 520 may form a closed space 540. The atmosphere within such space cannot be discharged from the closed space, so that when the multi-layered wiring board operates, it generates heat, whereby the semiconductor chip 531 may be heated or the gas within the space may expand to bend, which deforms the wiring board 510 or 520. In order to avoid this issue, the embodiment shown in FIG. 7(c) has the through hole 515 which discharges the atmosphere in the space 540. The formation of such through hole is not essential, but preferable in the present invention when the closed space 540 is formed, and air is confined therein.

The connector sheet of the present invention may be used in combination with a surface mount device. With reference to FIGS. 8(a) to 8(c), electrically connecting the surface mount device and the wiring board element will be described.

First, as shown in FIG. 8(a), a surface mount device 530 and the connector sheet 100 according to the present invention are prepared. The space mount device 530 is for example a bare chip semiconductor element. Similarly to the above, the connector sheet 100 may be replaced with the connector sheet 101, 102 or 103.

Then, as shown in FIG. 8(b), the surface mount device 530 is tentatively adhered to the connector sheet 100 by means of the tackiness of the connector sheet 100 under the first condition, and thereafter they are placed above the wiring board 550 (corresponding to the wiring board element) which is a multi-layered wiring board in the shown embodiment.

Then, as shown in FIG. 8(c), the surface mount device 530 is tentatively electrically connected to the wiring board 550 through the connector sheet 100 under the first condition under the first condition. Due the tackiness of the connector sheet, the wiring board 550 is tentatively adhered to the connector sheet 100. In the state shown in FIG. 8(c), the inspection is carried out as to the electric connection state between the surface mount device 530 and the wiring board 550. When the inspection indicates no problem, they are subjected to the second condition, so that the tentative adhesion is converted to the permanent adhesion. When the failure is indicated, the repair is carried out.

It is usual that the electric connection between the surface mount device 530 and the wiring board 550 is achieved by using a solder material, but using the connector sheet according to the present invention also achieves the electric connection. With the connector sheet, no step is required for melting the solder material. Further, the surface mount device has narrow pitch terminals, to which the connector sheet is able to adapt.

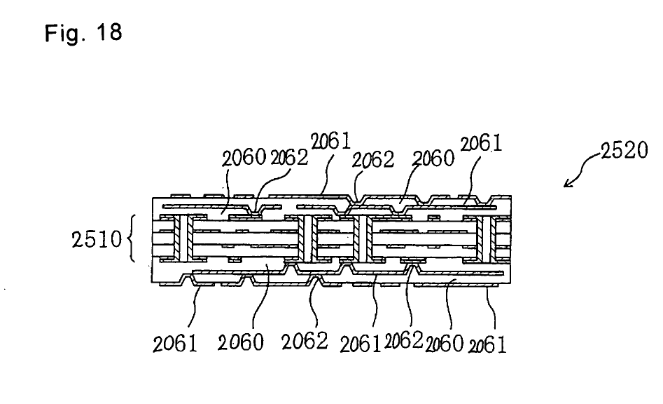

The present inventors have studied to develop a multi-layered wiring board which is inexpensive and to which finely wiring is applicable, and considered advantages and disadvantages of the glass/epoxy resin multi-layered wiring board and the buildup wiring board. FIG. 17 is a schematic cross-sectional view of a typical glass/epoxy resin multi-layered wiring board, while FIG. 18 is a schematic cross-sectional view of a typical buildup wiring board.

The glass/epoxy resin multi-layered wiring board 2510 shown in FIG. 17 comprises insulation layers 2050 of a glass woven fabric and an epoxy resin as well as copper foil layers 2051 formed both sides of each of the insulation layers 2050, so that a laminate 2055 of the insulation layers 2050 and the copper foil layers 2051 is formed. Through holes 2052 are formed through the laminate, and a plated layer 2053 of copper is formed on the inner wall of each through hole. As an outermost layer of the laminate 2055, a copper foil layer 2054 is formed as a wiring pattern, and the plated layer 2053 is formed also on the copper foil layer 2054.

Through the researches and developments of the glass/epoxy resin wiring board 2510 over the years, the production process there of has been established, and the production amount thereof is huge. Thus, the production cost of the glass/epoxy resin wiring board is smaller than that of the buildup wiring board. On the other hand, a wiring thickness of the glass/epoxy resin wiring board is larger, so that finely wiring is difficult. For example, the thickness of the copper foil layer 2054 may be reduced to about 18 to 35 μm, but the thickness of the plated layer 53 is at least 20 μm, so that the wiring thickness becomes large. With such large wiring thickness, it is difficult to form a multi-layered wiring board on which a semiconductor device (such as a semiconductor device package or a bare chip) having a terminal pitch of not larger than about 0.3 mm can be mounted. Since a glass woven fabric is used for the insulation layer 2050 of the glass/epoxy resin multi-layered wiring board 2510, surfaces of the wiring board have undulations without a flattening treatment due to undulations of the glass woven fabric. In fact, the undulation is about 5 μm as a level difference between the top and the trough of the undulation. When such undulations are present, finely wiring becomes difficult because of exposure accuracy. On the other hand, when sufficient flattening treatment is to be done, it increases the production cost.

The through holes 2052 are formed in the glass/epoxy multi-layered wiring board 2510, and the through holes limit the wiring area so that a wiring to be formed has to bypass the through holes, whereby a length of the wiring is increased. In addition, automatic wiring with CAD becomes difficult, and adaptation of drilling to the high density wiring is also difficult, which increases the drilling cost. Further, it is difficult to mount an electronic part above the through hole 2052, which is adverse to effective use of the mounting area, so that high density mounting of the parts is prevented.

Therefore, it is usual to use the buildup wiring board 2520 as shown in FIG. 18 when the semiconductor device having a fine terminal pitch is mounted. The buildup wiring board 2520 as shown in FIG. 18 comprises a glass/epoxy resin multi-layered wiring board 2510 as a core wiring board and buildup layers on its both sides each of which layers comprises an insulation layer 2060 and a wiring layer (plated layer) 2061. The connection between the wiring layers 2061 is achieved through via hole conductor 2062. The buildup wiring board 2520 shown in FIG. 18 is a 2+4+2 type board wherein the core board 2510 includes four wiring layers, and the buildup layer includes two wiring layers.

With the buildup board 2520, the fine and high density wiring is possible as described above, and therefore it is possible but expensive to form a printed wiring board onto which a semiconductor device having a fine terminal pitch can be mounted. This is because a number of steps (such as buildup layer forming, polishing, and plating) are to be done for the formation of the buildup board 2520. On each side of the core board, the buildup layers of the same number are to be formed, which increases the cost even though no device is mounted on one side of the core board. The reason why the buildup layers of the same number are formed is to avoid warpage occurrence of the buildup board, which warpage leads to failure. In addition, even when the number of wiring layers is to be increased only in a portion where an electronic part is mounted, designing such configuration is difficult from a viewpoint of the production process of the wiring board, so that the number of the wiring layers is required to be increased over an entire side of the board. It is noted that since the buildup board in which all are the buildup layers (such as ALIVH , or B²it™) has no through hole, it is advantageously versatile in the wiring design, but a number of the buildup layers (including those of the core board) are to be formed, which is expensive in the production of the buildup wiring board.

Based on the above matters as to the glass/epoxy resin multi-layered wiring board as well as the buildup wiring board, the inventors have found that when a sheet element which comprises a wiring layer on at least one surface (or side) thereof and a plurality of conductive members through the sheet element is installed on the a wiring board, partially more wiring layers can be achieved in a product wiring board, which results in the above mentioned invention of “other aspect”. Said conductive members may be the same as those of the above described connector sheet of the present invention. The sheet element may be a conventional insulation material used for the wiring board. However, in the second invention, it is preferable to use as such sheet element, the above described connector sheet according to the present invention which has a wiring layer on at least one side of the sheet substrate. Embodiments of the invention of said other aspect will be described hereinafter with reference to the accompanying drawings while explaining mainly embodiments wherein the connector sheet according to the present invention is used.

### EMBODIMENT 4

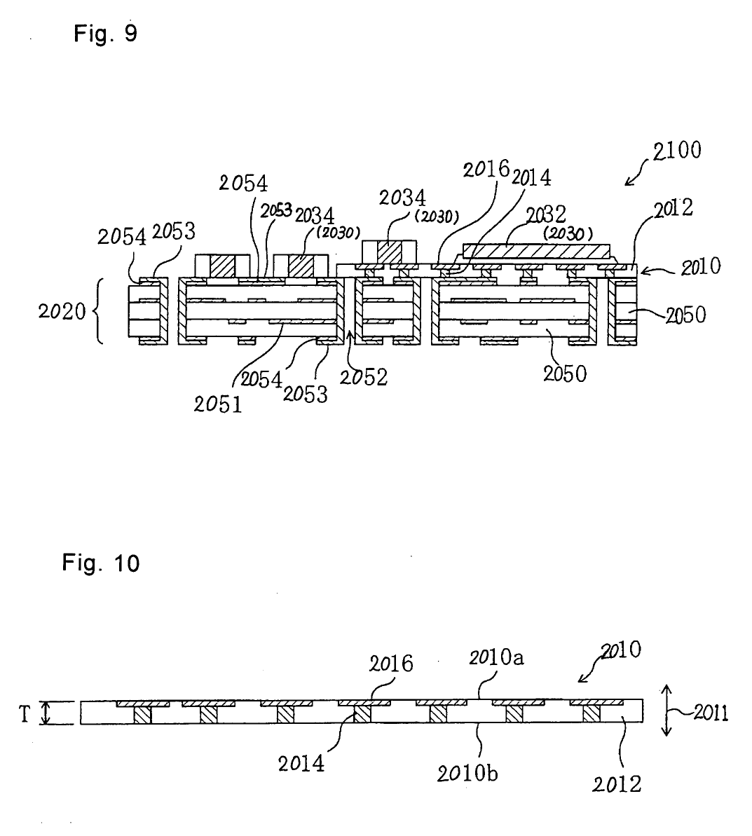

With reference to FIGS. 9 and 10, a multi-layered wiring board of Embodiment 4 will be explained. FIG. 9 is a schematic cross-sectional view of the multi-layered wiring board 2100, and FIG. 10 is a schematic cross-sectional view of the connector sheet 2010 having a wiring layer 2016 which is preferably used as said sheet element. The second invention is therefore explained mainly with embodiments as examples wherein the connector sheet is used.

The multi-layered wiring board 2100 of this embodiment comprises a core multi-layered (or double-sided layer) wiring board 2020 having at least two wiring layers (2051 and 2054) and a connector sheet 2010 having a wiring layer 2016 which sheet is attached to a portion of one surface (or side) of the core wiring board 2020. The shown connector sheet 2010 comprises a sheet substrate 2012 which has a front surface 2010a on which the wiring layer 2016 is formed and a rear surface 2010b which is opposing to the front surface, and conductive members 2014 which pass through the sheet substrate 2012 along a thickness direction 2011 of the sheet substrate 2012. It is noted that a further wiring layer may be placed also on the rear surface 2010b of the substrate sheet. The connector sheet has the tackiness under the first condition while develops the adhesiveness under the second condition.

The core wiring board 2020 is composed of an organic resin, a reinforcement material and metal layers (2051, 2052, 2053 and 2054). In the shown embodiment, the core wiring board 2020 is for example a glass/epoxy resin multi-layered wiring board (such as FR-4) wherein the organic resin is for example an epoxy resin, and the reinforcement material is for example a glass fiber fabric. The inside and the outside wiring layers 2051 and 2054 of the core wing board are made of copper foils. In the embodiment shown in FIG. 9, through holes 2052 are formed in the core wiring board 2010, and plated layers 2053 of copper are formed on the inner walls of the through holes 2052. The plated layers 2053 are also formed on the wiring layers 2054 on the outside of the core wiring board. It is noted that the shown core wiring board is a multi-layered wiring board having four wiring layers, which may be replaced with a double-sided layer wiring board having two wiring layers.

The connector sheet 2010 functions to allows the number of the wiring layers of only a certain portion of the multi-layered wiring board 2100 to be larger than the number of the wiring layers of the core wiring board 2020. In the embodiment shown in FIG. 9, the number of the wiring layers is four, while the number of the wiring layers of the region of the multi-layered wiring board 2100 in which region connector sheet is attached to is five. Contrary to the buildup wiring board 2520 as shown in FIG. 18, the multi-layered wiring board 2100 of the present embodiment achieves the partially multi-layering by means of the connector sheet 2010 having the wiring layer 2016, not using a buildup layer (2060 or 2061), so that even partly multi-layering on only one side of the core wiring board suppresses the warpage of the wiring board. Particularly, when the sheet substrate of the connector sheet 2010 includes the inorganic filler so that the thermal expansion coefficient of the connector sheet is accommodated to that of the core wiring substrate, the suppression of the warpage is further accelerated. It is noted that the shown embodiment has the connector sheet 2010 on only a portion of one side of the core wiring board 2020, but it is possible that each side of the core wiring board has a connector sheet on a portion thereof.

Electronic parts 2030 (2032 and 2034) are mounted on the connector sheet 2010. For example, the electronic parts 2030 are a semiconductor device (such as a semiconductor device package or a bare chip) 2032 and a passive part (such as a chip capacitor, a chip inducer or a chip resistor) 2034. Those electronic parts 2030 are electrically connected to the wiring layer(s) of the core wiring substrate 2020 through the connector sheet 2010. Particularly, terminals of the electronic part 2030 are connected to the wiring layers 2016 placed on the front surface 2010a of the connector sheet 2010, and the conductive members 2014 connected to the wiring layer 2016 is electrically connected to the wiring layer (2053 or 2054) of the core wiring board 2020.

It is noted that when the connector sheet according to the present invention is not used (i.e. said sheet element as described above is used which comprises a wiring layer on at least one surface thereof and a plurality of conductive members through the element is installed), the electric connection between the sheet element 2010 and the core wiring board 2020 may be achieved by means of for example soldering between the conductive members 14 exposed at the rear surface 2010b of the sheet element 2010 and the wiring layer of the core wiring board 2020. Alternatively, it is also possible that the rear surface 2010b of the sheet element 2010 has adhesiveness, which achieves the above electric connection. In order to give the adhesiveness to the rear surface 2010b, an adhesive layer is formed on the rear surface. It is of course possible to give the adhesive layer to the front surface 2010a of the sheet element 2010.

In the embodiment shown in FIG. 9, the electric parts 2034 (2030) are mounted also onto the core wiring substrate 2020. As shown in FIG. 9, when the electronic part(s) 2030 is mounted onto the multi-layered wiring board 2100, the product multi-layered wiring board itself functions as a module. In the module 2100 shown in FIG. 9, the first surface mount devices 2030 (such as a chip part 2034) are installed on the core wiring board 2020, and the second surface mount devices 2030 (such as a semiconductor device 2032 and a chip part 2034) is installed on the connector sheet 2010 according to the present invention wherein the connector sheet 2010 comprises the sheet substrate 2012 made of a material containing a resin and the conductive members 2014 which connecting the front surface 2010a and the rear surface 2010b of the sheet substrate 2010. For example a semiconductor device of which terminal pitch is not larger than 125 μm may be mounted onto the connector sheet as the second surface mount device 2030. It is noted that the semiconductor device 2032 may be mounted on the core wiring board 2020.

As the core wiring board 2020, a less expensive glass/epoxy resin multi-layered wiring board may be used. A surface of such wiring board 2020 generally has an undulation larger than 5 μm due to the presence of the glass woven fabric. The “undulation” herein is a level difference between the top and the trough of the undulation of the board surface, and it corresponds to “maximum depth waviness” according to JIS B0631 3.2.6. A thickness of the outermost wiring layer of the outermost layer (i.e. a thickness of the plated layer 2053 plus a thickness of the copper foil layer 2054) of the core wiring board 2020 is for example not less than 12 μm. Therefore, it is difficult to form a finely patterned wiring layer on the less expensive glass/epoxy resin multi-layered wiring board 2010.

On the other hand, since the connector sheet 2010 is formed separately from the core wiring board 2020, it is easy to form a finely patterned wiring layer on the connector sheet 2010. In this embodiment, the wiring layer of the connector sheet 2016 includes a wiring portion of which wiring pitch is not larger than 200 μm. Further, the wiring layer 2016 of the connector sheet 2010 may be formed by a transfer method as will be described below, which means that a thin copper foil may be used for the wiring layer. Thus, the connector sheet having the transferred wiring layer is suitable for the formation of the fine wiring layer, and the wiring layer can have a thickness not larger than for example 12 μm. When the conductive members are formed of the conductive paste and thus formed conductive members are electrically connected to the wiring layer, no copper plated layer has to be formed as the outermost layer, which allows fine wiring.

Generally, when the undulation is larger than 5 μm, it is difficult to form a buildup layer having a fine wiring layer (2060, 2061). However, in the present invention, the connector sheet 2010 having the wiring layer 2016 is installed onto the core wiring board 2020, so that the undulation of the core wiring board surface as a substrate affects not so much as far as the undulation is within a commercial specification of the core wiring board. The undulation of the connector sheet 2010 may be limited to for example not larger than 3 μm. Since the connector sheet 2010 having the already formed wiring layer is adhered to the core wiring board 2020, the undulation of the core wiring board surface does not cause a substantive problem. It is noted that the connector sheet 2010 may be preferably applied to the core wiring board 2020 of which surface has been subjected to a flatten treatment so that its undulation is not larger than 5 μm, since attaching the connector sheet 2010 to the flattened core wiring board 2020 is more convenient and less expensive than forming the buildup layer (2060, 2061).

According to this embodiment, by placing the connector sheet 2010 on only a portion of a side of the core wiring board 2020, partially more multi-layered structure may be readily formed which has a fine and high density wiring layer 2016 without using the buildup method. As a result, the multi-layered wiring board 2100 having a fine and high density wiring layer 2016 can be produced with a lower cost. Since the multi-layered wiring board 2100 according to this embodiment is produced by placing the connector sheet 2010 selectively on a portion of a core wiring substrate 2020 on which portion a semiconductor device 2032 having fine pitch terminals is mounted, no additional layer is not required to be formed over an entire surface of the core wiring board 2020, which differentiates the product wiring board according to the present invention from the buildup wiring board 2520. That is, in the buildup wiring board, the buildup layer (2060, 2061 ) is required to be formed over the entire surface of the core wiring board including the portion on which the semiconductor device is not located. To the contrary, in the multi-layered wiring board according to the present invention, the connector sheet is to be located on only a portion where the semiconductor device is located, which can be readily and effectively carried out. In other words, in spite of that an area on which the buildup layer is required is only a portion on which the semiconductor device having the fine terminal pitch is located, the buildup layer (2060, 2061) which allows a fine wiring layer to be formed over an entire surface of the core wiring board has to be formed in the case of the buildup wiring board, which leads to a lot of waste of the buildup layer.

In addition, in the case of the buildup wiring board 2520, the number of the buildup layers (2060, 2061) has to be the same on each side of the core wiring board 2020 so as to avoid the occurrence of warpage as described above, which leads to further waste. Particularly, when no semiconductor device is mounted onto a rear side of the core wiring board, such waste becomes more. Locating the connector sheet 2010 on only a portion of a side of a core wiring board 2020 causes substantially no warpage problem, and therefore, it is possible to locate the core sheet 2010 on only one side of the core wiring board 2020. In order to avoid the warpage problem more completely, the thermal expansion coefficient of the connector sheet 2010 may be adjusted to correspond to that of the core wiring board 2020.

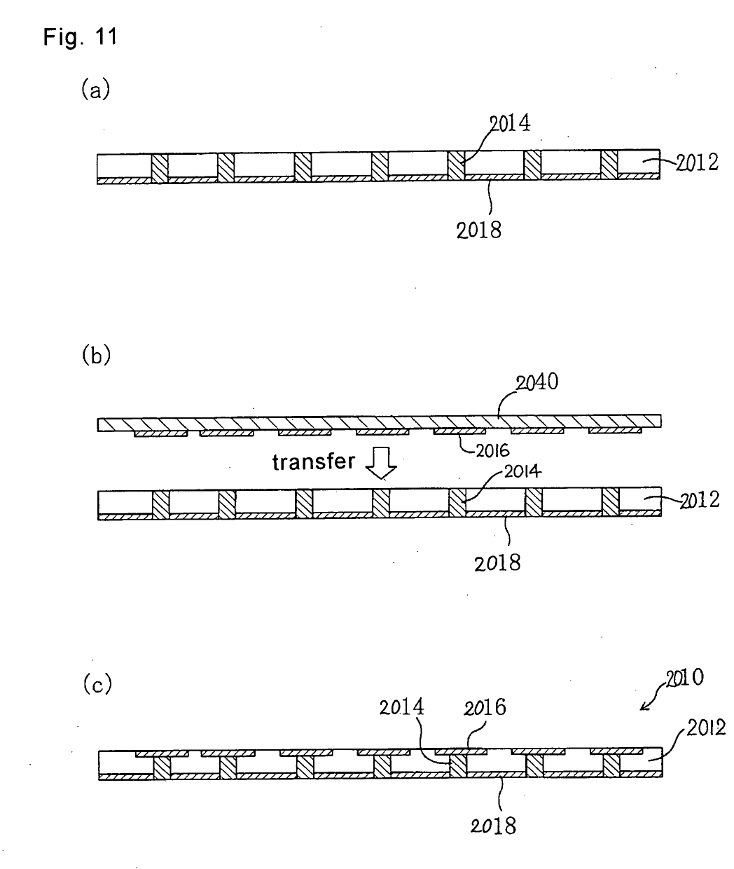

Then, a production process of the connector sheet 2010 which may be used for producing the above described multi-layered wiring board will be described with reference to FIGS. 11(a) to 11(c).

As shown in FIG. 11(a), a sheet substrate 2012 is formed on a release film 2018 and then the conductive members 2014 are formed through the sheet substrate 2012. In the shown embodiment, the through holes are formed through the sheet substrate 2012, and filled with a conductive paste to form the conductive members 2014. The conductive paste comprises for example a liquid thermoset resin and an electrically conductive metal filler. The other manner such as embedding a metal wire or metal balls may be used for preparing the conductive members 2014.

The release film 2018 attached to one side of the connector sheet 2010 makes handling of the sheet substrate 2012 (and therefore the connector sheet 2010) easy. When the rear surface of the sheet substrate 2012 is very tacky, the sheet substrate 2012 can be handled without minding the tackiness of the sheet substrate, so that the release film is effective. The release film is readily removed from the sheet substrate 2012 when its tackiness is used for the tentative adhesion. The release film may be made of for example PE, PET, PPS or PEN.

Then, a transfer sheet having a patterned wiring layer 2016 on a carrier sheet 2040 is prepared and the wiring layer 2016 is transferred to the sheet substrate 2012. The wiring layer 2016 may be formed by placing a metal layer such as a copper foil on the carrier sheet 2040 followed by etching using a predetermined mask. The carrier sheet 2040 may be made of a metal foil such as a copper foil or aluminum foil or a resin sheet. Thicknesses of the wiring layer 2016 and the carrier sheet are about 3 to 50 μm and about 25 to 200 μm respectively.

By carrying out the transfer, the connector sheet 2010 having the wiring layer 2016 is obtained as shown in FIG. 11(c). When the release film 2018 is removed, the connector sheet 2010 may be applied under the first condition to the core wiring substrate 2020 for the tentative adhesion using its tackiness under the first condition. After the tentative adhesion, when no failure is indicated in the inspection, the core wiring board including the connector sheet may be subjected to the second condition so as to convert the tentative adhesion to the permanent adhesion.

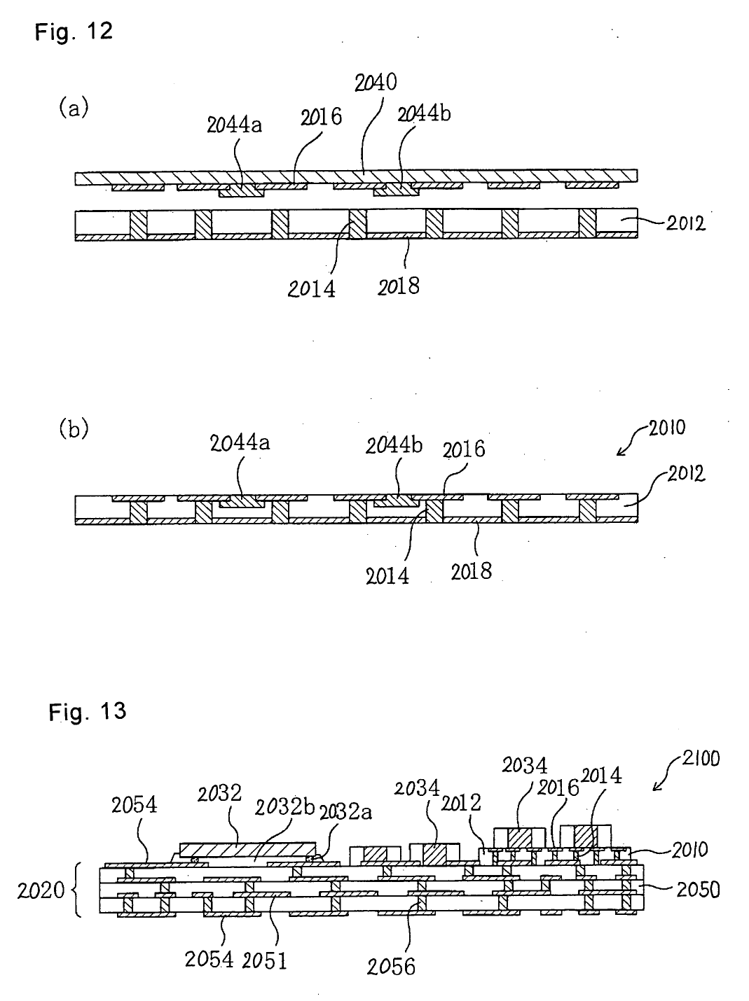

In the shown embodiment, only the wiring layer 2016 is transferred to the sheet substrate 2012, but it is optionally possible to transfer also a passive part (such as a film part). FIGS. 12(a) and 12(b) show the steps of transfer not only the wiring layer 2016 but also a resistor 2044a and a capacitor 2044b.

As shown in FIG. 12(a), the resistor 2044a and the capacitor 2044b are placed together with the wiring layer 2046 on the carrier sheet 2040, and then they are transferred as shown in FIG. 12(b), which results in the connector sheet having the resistor 2044a and the capacitor 2044b. The connector sheet can have a further function by including the passive parts therein, and using such connector sheet leads to effective using of a mounting area.

The connector sheet obtained as described above is attached to a portion of a surface of the core wiring board 2020 (for example, a portion where a fine wiring layer is to be provided). Then, an electronic part 2030 is mounted onto at least one of the connector sheet 2010 and the core wiring board 2020, so that a module 2100 comprising the core wiring board 2020 is obtained. It is noted that the connector sheet 2010 already having the mounted electronic part 2030 may be attached to the core wiring board 2020, or the electronic part 2030 may be attached to the connector sheet 2010 which has already been mounted onto the core wiring board 2020. When the connector sheet according to the present invention is used upon such attaching, the tackiness of the connector sheet is used for the tentative adhesion under the first condition, which thereafter may be converted to the permanent adhesion under the second condition optionally after the inspection of the electric connection formed through the tackiness of the connector sheet.

When the connector sheet 2010 in this embodiment is mounted on a predetermined part of the core wiring board, the wiring layer of the connector sheet may function as a circuit pattern selectively on such predetermined part which circuit pattern forms a certain circuit with other circuit pattern of the core wiring board through the electric connection with the conductive members of the connector sheet. Therefore, such circuit pattern of the core wiring board may form other circuit in the product wiring board when the connector sheet having a different circuit pattern as the wiring layer is mounted on the core wiring board. This means that the connector sheet may change the circuit of the product wiring board when the connector sheet has a different wiring layer thereon. To the contrary, all of the circuit configuration have to be re-designed and an entire of a new wiring board has to be produced even when a minor circuit change is carried out in the buildup wiring board.

As to the multi-layered wiring board 2100 according to the present invention, since multi-layering is carried out by means of the connector sheet 2010, a less expensive wiring board such as glass/epoxy resin wiring board can be used as a core wiring board as it is. Further, it is possible for only a portion where a semiconductor device requiring a fine wiring pitch is mounted to have a fine wiring layer, which is very effective.

Only substantially attaching the connector sheet 2010 to the core wing board provides the multi-layered wiring board 2100, so that no plating step or no etching step is required, and therefore the multi-layered wiring board 2100 can be produced even by a manufacturer which is not a wiring board manufacturer. That is, the additional wiring layer may be formed substantially only the transferring step contrary to the production of the buildup wiring board. Since the wiring layer is formed by means of transferring not plating, a thin copper foil may be used so that fine wiring is relatively easily possible, which leads to a lower cost. Further, using the connector sheet 2010 makes configuration modification of the product multi-layered wiring board by means of changing parts very easy.

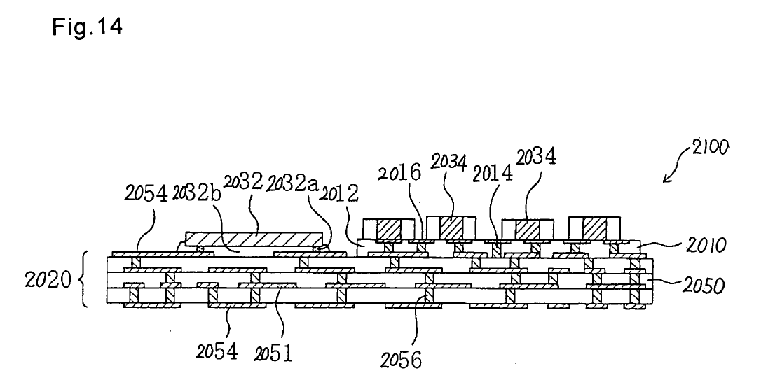

In the above, the glass/epoxy resin multi-layered wiring board is used as the core wiring board 2020, it is also possible to use the buildup wiring board. That is, the buildup wiring board 2520 shown in FIG. 18 is used as a core wiring board 2020, and the connector sheet 2020 may be attached to the buildup wiring board. When an additional buildup layer (2060, 2061) is desired to be formed on the buildup wiring board 2520, such buildup layer should be formed on the both sides of the core wiring board, which means one buildup layer is of no use. Increase in the number of the buildup layers to be formed leads to the cost increase. In this sense, the partial wiring layer increase by means of the connector sheet is very effective. In order to produce a multi-layered wiring board, it is possible to attach the connector sheet 2010 to the buildup board in which all layers are the buildup layers (such as ALIVH™, or B²it™). FIGS. 13 and 14 show a multi-layered wiring board 2100 comprising, as the core wiring board, such buildup wiring 2020 board without a through hole wherein the connector sheet is placed for the purpose of partly more multi-layering.

In the multi-layered wiring board shown in FIG. 13, a semiconductor device 2032 and a chip part 2034 are mounted on the core wiring board 2020, and a connector sheet 2010 on which a chip part 2034 is mounted is attached to the other part of the core wiring board. In the multi-layered wiring board shown in FIG. 14, a semiconductor device 2032 is mounted on the core wiring board, and a connector sheet 2010 on which chip parts 2034 are mounted is attached to other part of the core wiring board.

In the both embodiments shown in FIGS. 13 and 14, it is possible to mount a semiconductor device on the connector sheet 2010 as shown in FIG. 9. In the core wiring board shown in FIGS. 13 and 14, via hole conductors (or inner via holes, IVH) 2056 are formed which connect the wiring layers. In the both embodiments shown in FIGS. 13 and 14, the semiconductor device 2032 is connected to the core wiring board 2020 through the terminals (or bumps) 2032a, and underfill 2032b is filled between the semiconductor device 2032 and the core wiring board 2020.

### EMBODIMENT 5

The connector sheet according to the present invention is used as a connector sheet 2010 in this embodiment. Such connector sheet (particularly its front surface and rear surface) has the tackiness under the first condition and develops the adhesiveness under the second condition.

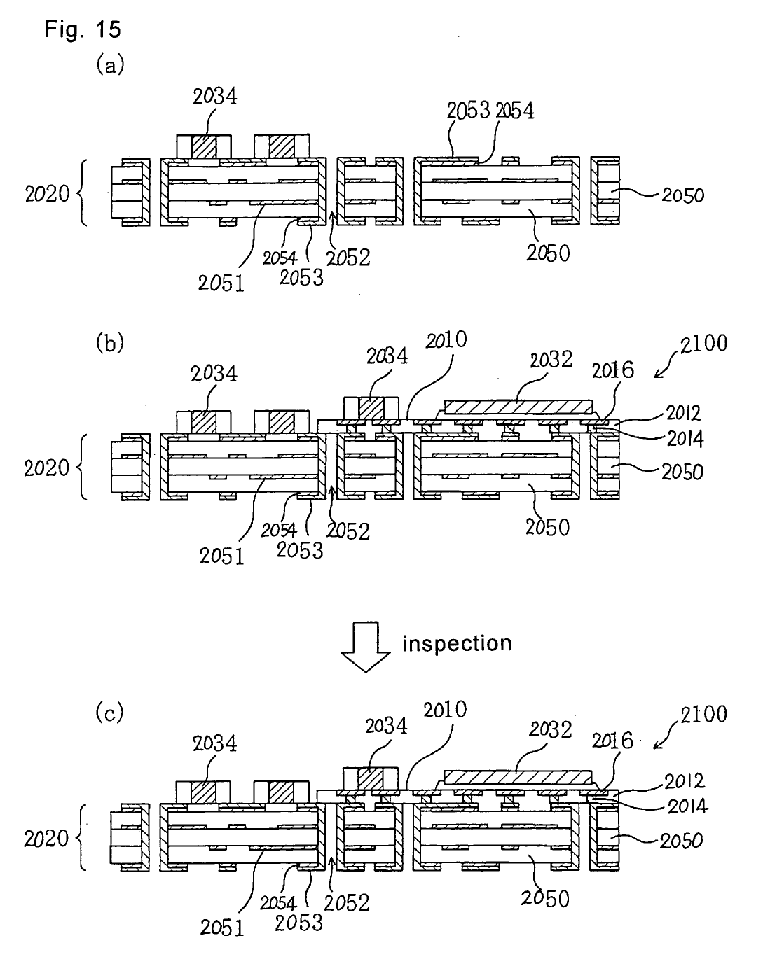

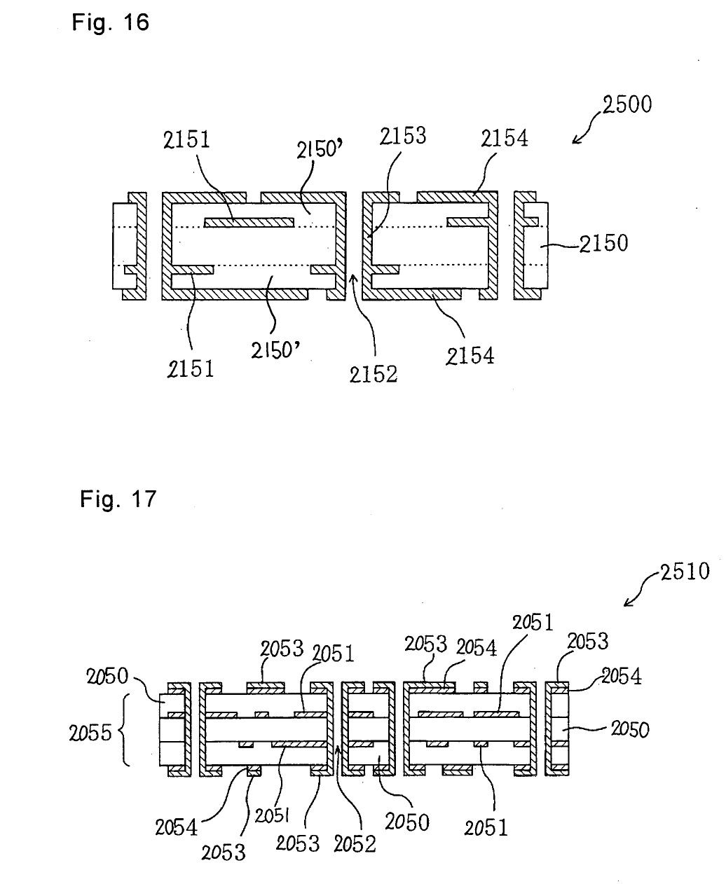

With reference to FIGS. 15(a) to 15(c), a method of connecting a core wiring board and an electronic part 2030 (2032, 2034) using the connector sheet 2010 is described.

As shown in FIG. 15(a), a core wiring board 2020 on which an electronic part (a chip part 2034) is mounted is prepared. As the core wiring board 2020, a glass/epoxy resin multi-layered wiring board may be used in this embodiment.

Then, the connector sheet on which electronic parts (2032, 2034) are attached is mounted is placed on a predetermined portion of the core wiring board 2020 under the first condition, so that the connector sheet 2010 and the core wiring board 2020 are tentatively adhered to each other by means of the tackiness of the connector sheet 2010. The first condition is for example a certain predetermined temperature between a room temperature and 80° C. Since the connector sheet 2010 contains the conductive members 2014 which ensures the electric conductivity between the top surface and the bottom surface of the connector sheet, so that the electric continuity between them is ensured without compression along the thickness direction of the connector sheet. It is noted that such compression allows the electric continuity to be ensured in the case of using an anisotropic conductive material such as ACF.

Then, as shown in FIGS. 15(b) and 15(c), inspection as to the electric connection state between the core wiring board 2020 and the connector sheet 2010 of the multi-layered wiring board (or module) 2100 is carried out. The inspection is carried out by determining an electric resistance as to a predetermined position of the multi-layered wiring board automatically with a multimeter and a scanner. When the inspection indicates no problem, the multi-layered wiring board is subjected to the second condition for example by raising the temperature around the wiring board so as to permanently adhere the connector sheet 2010 to the core wiring board 2020. The second condition comprises a certain temperature for example not lower than 140° C. (preferably between 150° C. and 170° C.). When subjected to the second condition, the connector sheet 2010 functions as an adhesive, so that the connector sheet 2010 and the core wiring board 2020 are permanently adhered contrary to being in the tentative adhesion condition.

When the above inspection indicated failure, the tentative adhesion state between the connector sheet 2010 and the core wiring board 2020 is disengaged and the connector sheet 2010 is removed under the first condition. Particularly, since the connector sheet 2010 is tentatively adhered to the core wiring board 2020 with the tackiness under the first condition, it is possible to remove the connector sheet with a small force. Thus, when the inspection indicates the failure, repairing (i.e. replacement of a member such as an electric part, a wiring board or the like) is easily possible, which reduces the number of disposed members due to the failure. Therefore, using the connector sheet 2010 decreases the production cost of the multi-layered wiring board.

When the connector sheet 2010 is removed after the state shown in FIG. 15(c), a manner to lower a temperature around the connector sheet may be employed so as to suppress the tackiness. That is, the tackiness may be suppressed when the temperature is decreased, which is utilized upon the removal of the connector sheet 2010. When the temperature upon the tentative adhesion of the connector sheet (i.e. the first condition) is for example between a room temperature and 80° C. sheet, such temperature may be lowered to a temperature lower than 0° C. and preferably between −10° C. and −20° C. It is also preferable that the connector sheet is formed such that its tackiness disappears when the third condition is reached wherein the temperature of the third condition is lower than the first condition.

As seen from the above, using the connector sheet 2010 having the tackiness under the first condition and the adhesiveness under the second condition allows the repairing.

With reference to the above embodiments, multi-layering has been described wherein the connector sheet having the wiring layer is placed on a portion of one side of the wiring board element so that the wiring layer is additionally added to such portion of the wiring board element. It is noted that an object to which the wiring layer is added is not limited to the wiring board elements as described above, it may be for example a portion of a casing (or a housing) of an electronic device. The casing not only has a number of concave and/or convex parts to form a complicated surface, but also often has a particular form like a box form. The connector sheet according to the present invention can be installed onto an inner surface of such casing so that the wiring layer can be added to the inner surface through the connector sheet even though such surface is complicated. Further, by attaching the connector sheet to a portion of the casing where a predetermined wiring layer has been already formed, such portion can have a more number of the wiring layers so that more multi-layered portion is formed inside the casing. Further, a electronic part may be attached to thus attached connector sheet in the casing or thus formed more multi-layered portion. When such multi-layering and/or attachment of the electronic part is carried out in the casing, miniaturization of the electronic devices can further proceed.

Using the connector sheet according to the present invention in the process for the production of the wiring board or module allows repairing. Also, the connector sheet provides the connection element which is adaptable to the fine wiring pitch. Thus, the connector sheet according to the present invention is useful for the production of multi-layered wiring board or module as various connection members.

According to the second invention, partly (more) multi-layering becomes possible, so that the multi-layered wiring board is provided which can be produced at a less cost.

Based on the above description, it is to be understood that the following various modes are included within the scopes of the present inventions: What is claimed is:

Mode 1. A connector sheet which comprises an insulation sheet substrate having a front surface and a rear surface opposing to the front surface, and electrically conductive members each passing through the sheet substrate along a thickness direction of the sheet substrate,
wherein the front surface and the rear surface contain a thermoset resin, and have tackiness under a first condition and develop adhesiveness under a second condition which is different from the first condition.

Mode 2. The connector sheet according to mode 1 wherein the first condition is a condition under which a curing reaction of the thermoset resin is not completed, and the second condition is a condition under which the curing reaction of the thermoset resin is compled.

Mode 3. The connector sheet according to mode 1 or 2 wherein the first condition is a condition under which a curing reaction of the thermoset resin does not occur.

Mode 4. The connector sheet according to any one of modes 1 to 3 wherein a material forming the front surface and the rear surface is selected the group consisting of:
(a) a combination of a silicone resin and a thermoset resin;
(b) a combination of a thermoplastic resin and a thermoset resin; and
(c) a combination of a ultraviolet curable resin and a thermoset resin.

Mode 5. The connector sheet according to any one of modes 1 to 4 wherein the first condition comprises a predetermined temperature or temperature range which is between 0° C. and 80° C., and the second condition comprises a predetermined temperature or temperature range which is not lower than 120° C.

Mode 6. The connector sheet according to any one of modes 1 to 5 wherein a material which forms the front surface and a material which forms the rear surface are the same.

Mode 7. The connector sheet according to any one of modes 1 to 6 wherein a whole of the sheet substrate is made of the same material.

Mode 8. The connector sheet according to any one of modes 1 to 6 wherein the sheet substrate comprised a middle layer, and a front surface layer located on a top side of the sheet substrate and a rear surface layer located on a bottom side of the sheet substrate.

Mode 9. The connector sheet according to mode 8 wherein the middle layer is made of a resin film or a layer in a cured state.

Mode 10. The connector sheet according to any one of modes 1 to 5, 8 and 9 wherein a material which forms the front surface and a material which forms the rear surface are different, the front surface has a first tack strength and the rear surface has a second tack strength which is different from the first tack strength.

Mode 11. The connector sheet according to any one of modes 1 to 10 wherein a release film is placed on at least one of the front surface and the rear surface.

Mode 12. The connector sheet according to any one of modes 1 to 11 wherein the sheet substrate or its front surface and rear surface contain a uniformly mixed tacky material.

Mode 13. The connector sheet according to any one of modes 1 to 12 wherein the sheet substrate comprises a wiring layer at least one of the front surface and the rear surface, and the wiring layer is connected to the conductive members.

Mode 14. The connector sheet according to any one of modes 1 to 13 wherein the sheet substrate or its front surface and rear surface contain an inorganic filler.

Mode 15. The connector sheet according to any one of modes 1 to 14 wherein the tackiness of the front surface and the rear surface under the first condition substantially disappears under a third condition of which temperature is lower than that of the first condition.

Mode 16. A method of electrically connecting a wiring board element and other wiring board element or an electric part comprising:
(a) placing the connector sheet according to any one of modes 1 to 15 on the wiring board element under the first condition so as to tentatively adhere the connector sheet to the wiring board element,
(b) placing said other wiring board element or the electric part on the connector sheet under the first condition so as to tentatively adhere said other wiring board element or the electric part to the connector sheet, and
(c) inspecting an electric connection state between the wiring board element and said other wiring board element or the electric part.

Mode 17. The method of electrically connecting according to mode 16 further comprising:
(d) forming permanent adhesion under the second condition between the connector sheet and the wiring board element, and forming permanent adhesion under the second condition between said other wiring board element or the electric part and the connector sheet when the electric connection state is found good though (c) the inspection.

Mode 18. The method of electrically connecting according to mode 16 further comprising:
(e) disengaging the tentative adhesion under the first condition between the connector sheet and the wiring board element, and disengaging the tentative adhesion under the first condition between said other wiring board element or the electric part and the connector sheet when the electric connection state is found bad though (c) inspecting.

Mode 19. The method of electrically connecting according to mode 18 further comprising:
carrying out (b) placing and (c) placing after (e) disengaging while using at least one selected from the group consisting of a fresh wiring board element, a fresh other wiring board element and a fresh electronic part.

Mode 20. The method of electrically connecting according to mode 18 or 19 wherein (e) disengaging is carried out under a third condition of which temperature is lower than that of the first condition.

Mode 21. The method of electrically connecting according to any one of modes 16 to 20 wherein an electronic part is mounted on the wiring board element.

Mode 22. A process of producing a product wiring board which comprises wiring board elements comprising:
(a) placing the connector sheet according to any one of modes 1 to 15 on a wiring board element under the first condition so as to tentatively adhere the connector sheet to the wiring board element,
(b) placing other wiring board element or the electric part on the connector sheet under the first condition so as to tentatively adhere said other wiring board element or the electric part to the connector sheet, and
(c) changing the first condition to the second condition so as to convert the tentative adhesion to permanent adhesion.

Mode 23. A product wiring board comprising the connector sheet according to any one of modes 1 to 15, and a first wiring board element and a second wiring board element,
wherein the plurality of the conductive members are exposed at a first surface and a second surface of the sheet substrate which second surface is opposed to the first surface,
the first wiring board element is located on the first surface and the second wiring board element is located on the second surface, and
the first wiring board element and the second wiring board element are electrically connected through the connector sheet.

Mode 24. The product wiring board according to mode 23 wherein a material which forms the first wiring board element is different from a material which forms the second wiring board element.

Mode 25. The product wiring board according to mode 23 or 24 wherein at least one of the first wiring board element and the second wiring board element is a flexible wiring board.

Mode 26. A product wiring board comprising a spacer substrate which has on its each side, the connector sheet according to any one of modes 1 to 15, a first wiring board element and a second wiring board element,
wherein the plurality of the conductive members are exposed at a first surface and a second surface of the sheet substrate which second surface is opposed to the first surface, and
the first wiring board element and the second wiring board element are electrically connected through the spacer substrate and the connector sheets on the both sides of the spacer substrate.

Mode 27. A product wiring board comprising an electronic part, a wiring board element and the connector sheet according to any one of modes 1 to 15, a first wiring board element and a second wiring board element,
wherein the connector sheet is located between the electronic part and the wiring board element.

Mode 28. The product wiring board according to mode 27 wherein the electronic part is a semiconductor chip which has terminals which are two-dimensionally arranged.

Mode 29. A product wiring board which comprises a wiring board elements having at least two wiring layers, and a sheet element located on a portion of a surface of the wiring board and having a wiring layer on its at least one side,
wherein the sheet element comprises:
a sheet material having a front surface on which the wiring layer is formed and a rear surface which is opposed to the front surface, and
a plurality of conductive members passing through the sheet material along its thickness direction.

Mode 30. The product wiring board according to mode 29 wherein the wiring board element has a surface of which undulation is not smaller than 5 μm.

Mode 31. The product wiring board according to mode 29 or 30 wherein the wiring layer of the wiring board element has a wiring portion of which wiring pitch is not larger than 200 μm.

Mode 32. The product wiring board according to any one of modes 29 to 31 wherein a thickness of the wiring layer of the wiring board element is not smaller than 12 μm, and a thickness of the wiring layer of the sheet element is not larger than 10 μm.

Mode 33. The product wiring board according to any one of modes 29 to 32 wherein the sheet element is located only one side of the wiring board element, and the sheet element partly increases the number of the wiring layers of the wiring board element.

Mode 34. The product wiring board according to any one of modes 29 to 33 wherein an electronic part is located on the sheet element.

Mode 35. The product wiring board according to any one of modes 29 to 34 wherein the sheet element has a passive part which is electrically connected to the wiring layer of the sheet element.

Mode 36. The product wiring board according to any one of modes 29 to 35 wherein the sheet element is the connector sheet according to any one of modes 1 to 15 which has a wiring layer on its at least one side.

Mode 37. The product wiring board according to any one of modes 29 to 36 wherein a second electronic part is located on the wiring board element.

Mode 38. The product wiring board according to mode 37 wherein the second electric part is a semiconductor device of which terminal pitch is not larger than 125 μm.

Mode 39. The product wiring board according to any one of modes 29 to 38 wherein a though hole is formed through the wiring board element.

Mode 40. The product wiring board according to any one of modes 29 to 39 wherein the sheet element has the wiring layer which is formed by a transfer method.

Mode 41. A process of producing a product wiring board comprising:
(a) preparing a wiring board element which includes at least two wiring layers;
(b) placing on a portion of a surface of the wiring board element, a sheet element comprising a sheet material which has a front surface having a wiring layer and a rear surface opposing to the front surface as well as a plurality of conductive members passing through the sheet material along its thickness direction, and
(c) mounting an electronic part on at least one of the wiring board element and the sheet element.

Mode 42. The process according to mode 41 wherein the sheet element is the connector sheet according to any one of modes 1 to 15.

Mode 43. The process according to mode 42 wherein
the wiring board element has a first circuit pattern which forms a portion of a circuit,
the wiring layer of the connector sheet has a second circuit pattern which forms other portion of the circuit, and
the first circuit pattern and the second circuit pattern together forms the circuit.

Mode 44. The process according to mode 42 or 43,
wherein the placement (b) is carried out under the first condition, whereby the connector sheet is tentatively adhered to the wiring board element, and
after mounting (c), inspection is carried out under the first condition in which electric connection between the wiring layer of the connector sheet and the wiring board element through the connector sheet is inspected.

Mode 45. The process according to mode 44 wherein when the electric connection is found good through the inspection, the first condition is changed to the second condition so that the connector sheet is permanently adhered to the wiring board element.

Mode 46. The process according to mode 44 wherein when the electric connection is found bad through the inspection, the tentative adhesion between the connector sheet and the wiring board element is disengaged under the first condition.

Mode 47. The process according to any one of modes 42 to 46 wherein the first condition comprises a predetermined temperature or temperature range which is between 0° C. and 80° C.

Mode 48. A method of inspecting an electric connection state between two electric members comprising:
(A) using the connector sheet according to any one of modes 1 to 15, under the first condition, one electric member is tentatively adhered to the front surface of the connector sheet, and the other electric member is tentatively adhered to the rear surface of the connector sheet, and
(B) then inspecting the electric connection state between these electric members.

Mode 49. The method according mode 48 wherein upon carrying out the inspection (B), a pressure is applied such that the electric members approach toward each other, and thereby the connection is inspected while a compression force is applied to the connector sheet.

1. A connector sheet which comprises an insulation sheet substrate having a front surface and a rear surface opposing to the front surface, and electrically conductive members each passing through the sheet substrate along a thickness direction of the sheet substrate,
wherein the front surface and the rear surface contain a thermoset resin, and have tackiness under a first condition and develop adhesiveness under a second condition which is different from the first condition.

2. The connector sheet according to claim 1 wherein the first condition is a condition under which a curing reaction of the thermoset resin is not completed, and the second condition is a condition under which the curing reaction of the thermoset resin is compled.

3. The connector sheet according to claim 1 wherein the first condition is a condition under which a curing reaction of the thermoset resin does not occur.

4. The connector sheet according to claim 1 wherein a material forming the front surface and the rear surface is selected the group consisting of:
(a) a combination of a silicone resin and a thermoset resin;
(b) a combination of a thermoplastic resin and a thermoset resin; and
(c) a combination of a ultraviolet curable resin and a thermoset resin.

5. The connector sheet according to claim 1 wherein the first condition comprises a predetermined temperature or temperature range which is between 0° C. and 80° C., and the second condition comprises a predetermined temperature or temperature range which is not lower than 120° C.

6. The connector sheet according to claim 1 wherein a material which forms the front surface and a material which forms the rear surface are the same.

7. The connector sheet according to claim 1 wherein a whole of the sheet substrate is made of the same material.

8. The connector sheet according to claim 1 wherein the sheet substrate comprised a middle layer, and a front surface layer located on a top side of the sheet substrate and a rear surface layer located on a bottom side of the sheet substrate.

9. The connector sheet according to claim 8 wherein the middle layer is made of a resin film or a layer in a cured state.

10. The connector sheet according to claim 1 wherein a material which forms the front surface and a material which forms the rear surface are different, the front surface has a first tack strength and the rear surface has a second tack strength which is different from the first tack strength.

11. The connector sheet according to claim 1 wherein a release film is placed on at least one of the front surface and the rear surface.

12. The connector sheet according to claim 1 wherein the sheet substrate or its front surface and rear surface contain a uniformly mixed tacky material.

13. The connector sheet according to claim 1 wherein the sheet substrate comprises a wiring layer at least one of the front surface and the rear surface, and the wiring layer is connected to the conductive members.

14. The connector sheet according to claim 1 wherein the sheet substrate or its front surface and rear surface contain an inorganic filler.

15. The connector sheet according to claim 1 wherein the tackiness of the front surface and the rear surface under the first condition substantially disappears under a third condition of which temperature is lower than that of the first condition.

16. A method of electrically connecting a wiring board element and other wiring board element or an electric part comprising:
(a) placing the connector sheet according to any one of claim 1 on the wiring board element under the first condition so as to tentatively adhere the connector sheet to the wiring board element,
(b) placing said other wiring board element or the electric part on the connector sheet under the first condition so as to tentatively adhere said other wiring board element or the electric part to the connector sheet, and
(c) inspecting an electric connection state between the wiring board element and said other wiring board element or the electric part.

17. The method of electrically connecting according to claim 16 further comprising:
(d) forming permanent adhesion under the second condition between the connector sheet and the wiring board element, and forming permanent adhesion under the second condition between said other wiring board element or the electric part and the connector sheet when the electric connection state is found good though (c) the inspection.

18. The method of electrically connecting according to claim 16 further comprising:
(e) disengaging the tentative adhesion under the first condition between the connector sheet and the wiring board element, and disengaging the tentative adhesion under the first condition between said other wiring board element or the electric part and the connector sheet when the electric connection state is found bad though (c) inspecting.

19. The method of electrically connecting according to claim 18 further comprising:
carrying out (b) placing and (c) placing after (e) disengaging while using at least one selected from the group consisting of a fresh wiring board element, a fresh other wiring board element and a fresh electronic part.

20. The method of electrically connecting according to claim 18 wherein (e) disengaging is carried out under a third condition of which temperature is lower than that of the first condition.

21. The method of electrically connecting according to claim 16 wherein an electronic part is mounted on the wiring board element.

22. A process of producing a product wiring board which comprises wiring board elements comprising:
(a) placing the connector sheet according to any one of claim 1 on a wiring board element under the first condition so as to tentatively adhere the connector sheet to the wiring board element,
(b) placing other wiring board element or the electric part on the connector sheet under the first condition so as to tentatively adhere said other wiring board element or the electric part to the connector sheet, and
(c) changing the first condition to the second condition so as to convert the tentative adhesion to permanent adhesion.

23. A product wiring board comprising the connector sheet according to claim 1, and a first wiring board element and a second wiring board element,
wherein the plurality of the conductive members are exposed at a first surface and a second surface of the sheet substrate which second surface is opposed to the first surface,
the first wiring board element is located on the first surface and the second wiring board element is located on the second surface, and
the first wiring board element and the second wiring board element are electrically connected through the connector sheet.

24. The product wiring board according to claim 23 wherein a material which forms the first wiring board element is different from a material which forms the second wiring board element.

25. The product wiring board according to claim 23 wherein at least one of the first wiring board element and the second wiring board element is a flexible wiring board.

26. A product wiring board comprising a spacer substrate which has on its each side, the connector sheet according to claim 1, a first wiring board element and a second wiring board element,
wherein the plurality of the conductive members are exposed at a first surface and a second surface of the sheet substrate which second surface is opposed to the first surface, and
the first wiring board element and the second wiring board element are electrically connected through the spacer substrate and the connector sheets on the both sides of the spacer substrate.

27. A product wiring board comprising an electronic part, a wiring board element and the connector sheet according to claim 1, a first wiring board element and a second wiring board element,
wherein the connector sheet is located between the electronic part and the wiring board element.

28. The product wiring board according to claim 27 wherein the electronic part is a semiconductor chip which has terminals which are two-dimensionally arranged.

29. A product wiring board which comprises a wiring board elements having at least two wiring layers, and a sheet element located on a portion of a surface of the wiring board and having a wiring layer on its at least one side,
wherein the sheet element comprises:
a sheet material having a front surface on which the wiring layer is formed and a rear surface which is opposed to the front surface, and
a plurality of conductive members passing through the sheet material along its thickness direction.

30. The product wiring board according to claim 29 wherein the wiring board element has a surface of which undulation is not smaller than 5 μm.

31. The product wiring board according to claim 29 wherein the wiring layer of the wiring board element has a wiring portion of which wiring pitch is not larger than 200 μm.

32. The product wiring board according to claim 29 wherein a thickness of the wiring layer of the wiring board element is not smaller than 12 μm, and a thickness of the wiring layer of the sheet element is not larger than 10 μm.

33. The product wiring board according to claim 29 wherein the sheet element is located only one side of the wiring board element, and the sheet element partly increases the number of the wiring layers of the wiring board element.

34. The product wiring board according to claim 29 wherein an electronic part is located on the sheet element.

35. The product wiring board according to claim 29 wherein the sheet element has a passive part which is electrically connected to the wiring layer of the sheet element.

36. The product wiring board according to claim 29 wherein the sheet element is the connector sheet according to any one of claim 1 which has a wiring layer on its at least one side.

37. The product wiring board according to claim 29 wherein a second electronic part is located on the wiring board element.

38. The product wiring board according to claim 37 wherein the second electric part is a semiconductor device of which terminal pitch is not larger than 125 μm.

39. The product wiring board according to claim 29 wherein a though hole is formed through the wiring board element.

40. The product wiring board according to claim 29 wherein the sheet element has the wiring layer which is formed by a transfer method.

41. A process of producing a product wiring board comprising:
(a) preparing a wiring board element which includes at least two wiring layers;
(b) placing on a portion of a surface of the wiring board element, a sheet element comprising a sheet material which has a front surface having a wiring layer and a rear surface opposing to the front surface as well as a plurality of conductive members passing through the sheet material along its thickness direction, and
(c) mounting an electronic part on at least one of the wiring board element and the sheet element.

42. The process according to claim 41 wherein the sheet element is the connector sheet according to claim 1.

43. The process according to claim 42 wherein
the wiring board element has a first circuit pattern which forms a portion of a circuit,
the wiring layer of the connector sheet has a second circuit pattern which forms other portion of the circuit, and
the first circuit pattern and the second circuit pattern together forms the circuit.

44. The process according to claim 42,
wherein the placement (b) is carried out under the first condition, whereby the connector sheet is tentatively adhered to the wiring board element, and
after mounting (c), inspection is carried out under the first condition in which electric connection between the wiring layer of the connector sheet and the wiring board element through the connector sheet is inspected.

45. The process according to claim 44 wherein when the electric connection is found good through the inspection, the first condition is changed to the second condition so that the connector sheet is permanently adhered to the wiring board element.

46. The process according to claim 44 wherein when the electric connection is found bad through the inspection, the tentative adhesion between the connector sheet and the wiring board element is disengaged under the first condition.

47. The process according to claim 42 wherein the first condition comprises a predetermined temperature or temperature range which is between 0° C. and 80° C.

48. A method of inspecting an electric connection state between two electric members comprising:
(A) using the connector sheet according to claim 1, under the first condition, one electric member is tentatively adhered to the front surface of the connector sheet, and the other electric member is tentatively adhered to the rear surface of the connector sheet, and
(B) then inspecting the electric connection state between these electric members.

49. The method according claim 48 wherein upon carrying out the inspection (B), a pressure is applied such that the electric members approach toward each other, and thereby the connection is inspected while a compression force is applied to the connector sheet.
